(19) United States
(12) Patent Application Publication
(10) Pub. No.: US 2012/0080391 A1
(43) Pub. Date: Apr. 5, 2012

(54) JIG USED FOR INSTALLING INFORMATION EQUIPMENT ON RACK AND INSTALLATION METHOD

(75) Inventors: Osamu NAKAMURA, Kahoku (JP); Kouichi OKAJIMA, Kahoku (JP)

(73) Assignee: FUJITSU LIMITED, Kawasaki-shi (JP)

(21) Appl. No.: 13/232,218

(22) Filed: Sep. 14, 2011

(30) Foreign Application Priority Data
Sep. 30, 2010 (JP) 2010-223226

(51) Int. Cl. H05K 7/14; B23P 11/00

(52) U.S. Cl. 211/26; 29/428

(57) ABSTRACT

An installation jig used for installing information equipment in a rack, the installation jig has a pair of slidable members extending in a direction heading from a near side to a fore side of the rack, stoppers preventing the slidable members to be pushed over a predetermined position in the fore side and knobs pulling out the slidable members from the near side. The slidable members each have an inclined surface with a planar portion and each have a bottom with a planar portion, the bottom being formed at the side opposite to the inclined surface. A height between the bottom and the inclined surface is decreased from the near side to the fore side, and the inclined surface and the bottom is formed by using a material with a low friction coefficient.

### CROSS-REFERENCE TO RELATED APPLICATIONS

This application is based upon and claims the benefit of priority of the prior Japanese Patent Application No. 2010-223226, filed on Sep. 30, 2010 the entire contents of which are incorporated herein by reference.

### FIELD

This application relates to a method for installing information equipment in a rack and a jig used for installing the information equipment.

### BACKGROUND

In the case where information equipment, for example heavy computer equipment such as a server, is installed in a rack, an installation method varies depending on use conditions of the installed computer equipment, such as maintenance after the installation. The installation method is broadly classified into a slide rail method in which a slide rail is used and into a non-slide rail method in which the slide rail is not used, depending on the following conditions: whether maintenance is conducted in a state in which the equipment has been installed in the rack; whether the equipment is removed from the rack for the maintenance; and the frequency of the maintenance and the weight of the equipment.

In the case of employing the slide rail method, the equipment is placed on a slide rail in which a slide rail mechanism utilizing bearings, rollers or the likes is used, and the equipment can be then easily moved back and forth in the rack. On the other hand, in the case of employing the non-slide rail method, the equipment is supported by a lifter or two to three persons, the end of the bottom of the supported equipment is then placed on L-shaped brackets attached to the rack, and the bottom of the equipment is slid on the brackets, thereby pushing the equipment into the inside of the rack. In the non-slide rail method, it is difficult to push heavy equipment into a home position inside of the rack.

FIG. 1 illustrates an example of traditional installation in which a slide rail is used. With reference to FIG. 1, a rack 100 has a configuration in which four steel columns 101-1 to 101-4 are vertically provided and in which an upper steel plate 102-1 and a lower steel plate 102-2 are respectively welded to the upper and lower portions of the steel columns. Furthermore, four inner steel columns 103-1 to 103-4 each having an L-shaped cross-sectional surface are provided to the inside of the rack 100, and ends of each of the inner steel columns are individually welded to the upper steel plate 102-1 and the lower steel plate 102-2. An outer rail 104-1 having a C-shaped cross-sectional surface is horizontally screwed to the inner columns 103-1 and 103-2. An outer rail 104-2 is screwed to the inner columns 103-3 and 103-4 at a height the same as that of the outer rail 104-1. A plurality of bearings or rollers (not illustrated) are held at the upper and lower portions inside a pair of the outer rails 104-1 and 104-2, thereby individually accommodating C-shaped inner rails 105-1 and 105-2 (invisible hidden by the equipment 107) inside the outer rails 104-1 and 104-2. The inner rails 105-1 and 105-2 are individually attached to the left and right surfaces of equipment 107 (see Japanese Laid-open Patent Publication No. 2007-4538). The equipment 107 is attached to the inner rails 105-1 and 105-2 while being supported by a lifter or two to three persons. The inner rails 105-1 and 105-2 are supported by the bearings or rollers which are each held at the upper and lower portions inside the outer rails 104-1 and 104-2. Stoppers (not illustrated) are provided at the two ends of the individual outer rails 104-1 and 104-2, thereby preventing separation of the inner rails 105-1 and 105-2. Owing to the supporting by the bearings or rollers inside outer rails 104-1 and 104-2, the equipment 107 attached to the inner rails 105-1 and 105-2 is moved in a direction indicated by an arrow in FIG. 1 and in a direction opposite thereto (see Japanese Laid-open Patent Publication No. 2007-4538). Equipment 108 placed at a lower position is similarly attached to outer rails 106-1 and 106-2 and can be therefore moved in a direction indicated by an arrow in FIG. 1 and in a direction opposite thereto.

FIG. 2 illustrates an example of traditional installation in which a slide rail is not used. With reference to FIG. 2, a rack 200 has a configuration in which four steel columns 201-1 to 201-4 are vertically provided and in which an upper steel plate 202-1 and a lower steel plate 202-2 are respectively welded to the upper and lower portions of the steel columns. Furthermore, four inner steel columns 203-1 to 203-4 each having an L-shaped cross-sectional surface are provided to the inside of the rack 200, and ends of each of the inner steel columns are individually welded to the upper steel plate 202-1 and the lower steel plate 202-2. An L-shaped bracket 204-1 is horizontally screwed to the inner columns 203-1 and 203-2, and an L-shaped bracket 204-2 is similarly screwed to the inner columns 203-3 and 203-4 at a height the same as that of the L-shaped bracket 204-1. Equipment 205 is supported by a lifter or two to three persons, and an end of the bottom of the supported equipment 205 is then placed on the L-shaped brackets 204-1 and 204-2. The equipment 205 is then pushed into a predetermined position in a direction indicated by an arrow. Equipment 207 is placed at a lower position of the rack 200 and is supported by L-shaped brackets 206-1 and 206-2 (invisible hidden by the equipment 207).

In the case where heavy equipment is installed in the rack and is then frequently moved inside the rack as described above, the slide rail method is preferably employed. In contrast, the non-slide rail method has a simple structure relative to that of the slide rail method and enables costs to be reduced. In the case where equipment is fixed to a rack with screws or the likes for installation and is subsequently less likely to be removed, the non-slide rail method is employed to install the equipment in the rack. In the case where many pieces of heavy equipment are installed in a rack with high density, space which is used to provide slide rails is decreased, and the slide rails cannot be therefore provided. The non-slide rail method is accordingly employed to install the equipments in the rack in some cases.

In the case of installing servers, the servers are installed inside a rack with high density, and the non-slide rail method is therefore employed for the installation inside the rack. The servers always require, however, quick maintenance and may be therefore frequently removed from and installed in the rack.

In the case where the non-slide rail method is employed to install heavy equipment in a rack, a large force is needed to push the heavy equipment into a predetermined position inside the rack. In the case where the non-slide rail method is employed to install a heavy server in a rack and in the case where the server is then repeatedly removed and returned with frequency, users suffer from a large burden especially when the server is returned to the rack.

In the case where the non-slide rail method is employed to install heavy equipment in a rack having reduced space, the sliding surfaces of the equipment and L-shaped brackets may be formed by using a low friction coefficient material. Employment of such a method unfortunately causes costs to be increased. In addition, the decrease of a friction coefficient is limited, and an effect of the decrease of sliding and pushing force is therefore limited.

### SUMMARY

According to an aspect of the application, a jig used for installing information equipment (hereinafter referred to as equipment, simply) in a rack includes a pair of slidable members which extend to a fore side which is a direction in which the equipment is installed in a rack; stoppers which serve to prevent the movement of the slidable members to the fore side; and knobs which serve to move the slidable members to a near side which is a direction opposite to the fore side. The slidable members each have an inclined surface with a flat portion and have a bottom with a flat portion, the bottom being positioned opposite to the inclined surface. The height between the bottom and the inclined surface is gradually decreased from the near side to the fore side. The inclined surface and the bottom are formed by using a low friction coefficient material. The bottoms are placed at a predetermined position on horizontal surfaces of a pair of brackets provided to the rack, the horizontal surfaces being positioned at the same height. The equipment is slid on the inclined surfaces from the near side to the fore side with the result that the fore-side end of the equipment abuts on a predetermined position on the horizontal surfaces.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF DRAWINGS

FIG. 1 illustrates an example of traditional installation in which a slide rail is used;

FIG. 2 illustrates an example of traditional installation in which a slide rail is not used;

FIG. 3A illustrates an installation jig of a first embodiment of the application;

FIG. 3B illustrates the installation jig of the first embodiment of the application;

FIG. 4A illustrates an example of first and second inclined surfaces;

FIG. 4B illustrates an example of the first and second inclined surfaces;

FIG. 5A illustrates an example in which the first installation jig is used;

FIG. 5B illustrates an example in which the first installation jig is used;

FIG. 5C illustrates an example in which the first installation jig is used;

FIG. 6 illustrates another example of the first inclined surface;

FIG. 7A illustrates another example of the second inclined surface;

FIG. 7B illustrates another example of the second inclined surface;

FIG. 8A illustrates an example of an inter-inclined surfaces region in which a pair of the first inclined surfaces are included;

FIG. 8B illustrates an example of the inter-inclined surfaces region in which a pair of the first inclined surfaces are included;

FIG. 9A illustrates relationship between a vertical line extending from the position of the center of gravity of equipment and the inter-inclined surface region;

FIG. 9B illustrates another relationship between the vertical line extending from the position of the center of gravity of the equipment and the inter-inclined surface region;

FIG. 10A illustrates the components of the installation jig of the first embodiment;

FIG. 10B illustrates the components of the installation jig of the first embodiment;

FIG. 10C illustrates the components of the installation jig of the first embodiment;

FIG. 11 illustrates the installation jig of the first embodiment in detail;

FIG. 12A illustrates the operation of the installation jig of the first embodiment;

FIG. 12B illustrates the operation of the installation jig of the first embodiment;

FIG. 12C illustrates the operation of the installation jig of the first embodiment;

FIG. 12D illustrates the operation of the installation jig of the first embodiment;

FIG. 13 illustrates force for pushing equipment with the installation jig;

FIG. 14 illustrates relationship between force for pushing equipment with the installation jig and the first inclined surface;

FIG. 15 illustrates force for withdrawing the installation jig;

FIG. 16 illustrates relationship between force for withdrawing the installation jig and the first inclined surface;

FIG. 17A illustrates an installation jig of a second embodiment;

FIG. 17B illustrates the installation jig of the second embodiment;

FIG. 18A illustrates an installation jig of a third embodiment;

FIG. 18B illustrates the installation jig of the third embodiment;

FIG. 19 illustrates an installation jig of a fourth embodiment;

FIG. 20 illustrates an installation jig of a fifth embodiment;

FIG. 21A illustrates an installation jig of a sixth embodiment;

FIG. 21B illustrates the installation jig of the sixth embodiment;

FIG. 22A illustrates an example in which the installation jig is used;

FIG. 22B illustrates an example in which the installation jig is used;

FIG. 22C illustrates an example in which the installation jig is used;

FIG. 22D illustrates an example in which the installation jig is used; and

FIG. 23 is a flowchart illustrating an installation method.

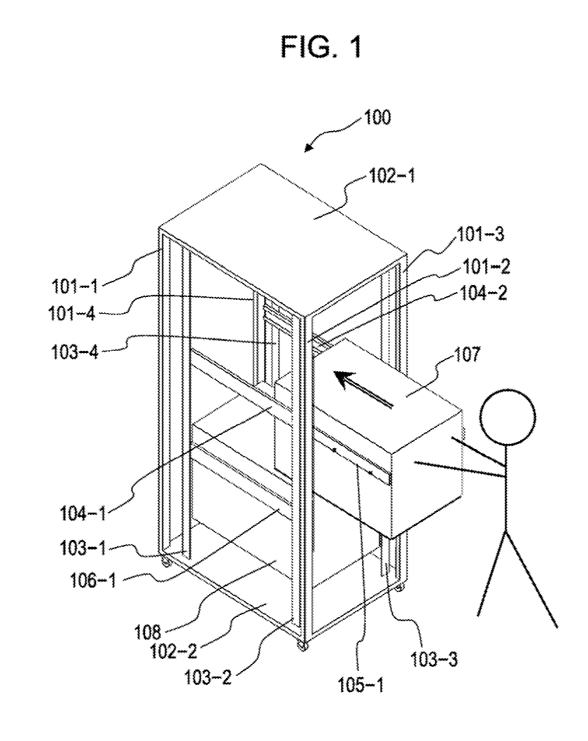

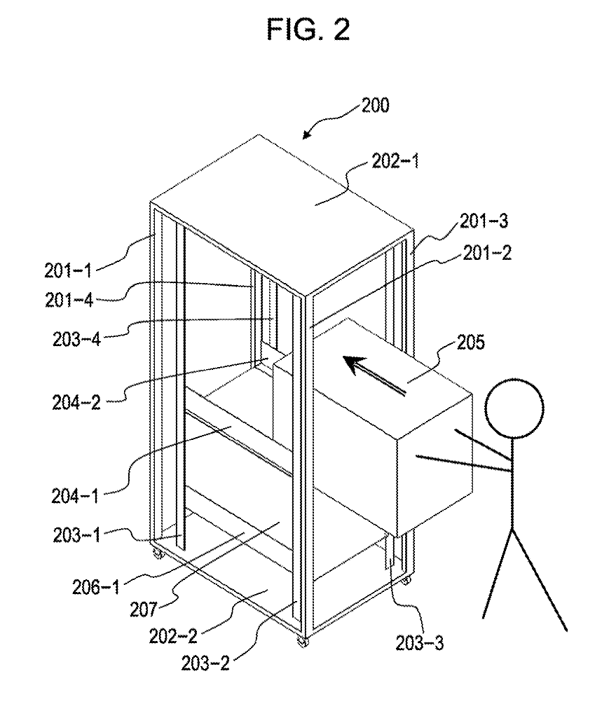

### DESCRIPTION OF EMBODIMENTS

An embodiment of the application is hereinafter described with reference to the accompanying drawings.

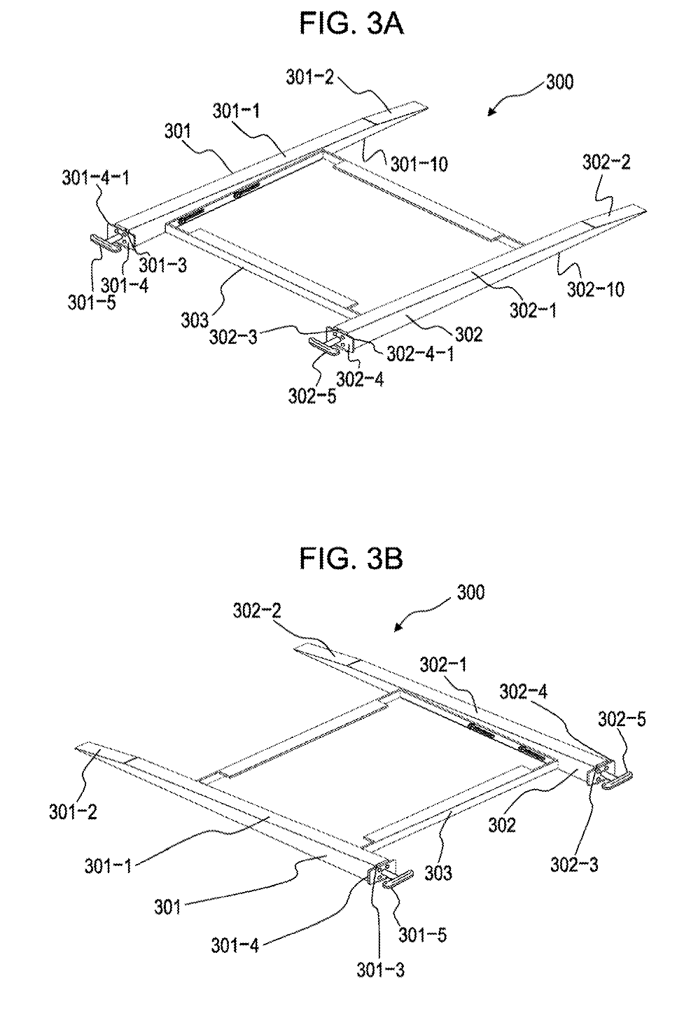

FIGS. 3A and 3B each illustrate an installation jig of a first embodiment.

FIG. 3A illustrates the appearance of an installation jig 300 viewed from the right-side front thereof. FIG. 3B illustrates the appearance of the installation jig 300 viewed from the left-side front thereof.

The installation jig 300 includes a pair of slidable members 301 and 302 and includes connection members 303 which serve to mechanically connect a pair of the slidable members 301 and 302 with, for example, screws.

The slidable member 301 has a first inclined surface 301-1 and a second inclined surface 301-2. The slidable member 302 has a first inclined surface 302-1 and a second inclined surface 302-2.

The thicknesses between the first inclined surface 301-1 and a bottom 301-10 and between the first inclined surface 302-1 and a bottom 302-10 (bottoms are located at invisible positions in the drawings) are decreased from ends 301-3 and 302-3 to the second inclined surfaces 301-2 and 302-2, respectively. The first inclined surfaces 301-1 and 302-1 function as sliding surfaces, and the bottom of equipment (not illustrated) is slid on the first inclined surfaces 301-1 and 302-1 from the near side, on which the ends 301-3 and 302-3 are provided, to the fore side, thereby pushing the equipment into the fore side.

In the case where the installation jig 300 is withdrawn from the equipment, the second inclined surfaces 301-2 and 302-2 function to smoothly withdraw the installation jig 300 from the equipment such that the equipment is not subjected to shock. In addition, the second inclined surfaces 301-2 and 302-2 serve to decrease the length of the fore side of the installation jig 300.

The slidable members 301 and 302 are used in the form of a pair. The slidable members 301 and 302 each preferably have the same appearance and size.

In the above description, the slidable members 301 and 302 each have the same appearance and size except screw holes through which the slidable members 301 and 302 are screwed to the connection members 303. Meanwhile, in the case where any one of the slidable members 301 and 302 is illustrated and described in each of the drawings, illustration and description of the other one are omitted.

Examples of a material of each of the slidable members 301 and 302 include a trimmed material having a low friction coefficient, such as fluororesin, nylon resin, or polyethylene resin. Alternatively, a metallic material such as an aluminum alloy or titanium alloy is employed as a base member, and at least the first inclined surfaces 301-1 and 302-1, the second inclined surfaces 301-2 and 302-2, and the bottoms 301-10 and 302-10 are subjected to surface treatment, the bottoms 301-10 and 302-10 being respectively positioned opposite to the first inclined surfaces 301-1 and 302-1. For example, a plate made of a fluororesin, nylon resin, or polyethylene resin and having a predetermined thickness is attached, or coating is applied so as to have a predetermined thickness. Furthermore, among surfaces of the base member, at least the first inclined surface, second inclined surface, and bottom positioned opposite to the first inclined surface may be subjected to surface treatment in which electroless nickel plating containing fluorine particles is used.

The connection members 303 are made of, for example, a metallic plate. The connection members 303 serve to hold a constant distance between the slidable members 301 and 302 and serve to withdraw the installation jig 300 in stages, the installation jig 300 having been used to press the equipment into a predetermined position inside a rack (not illustrated).

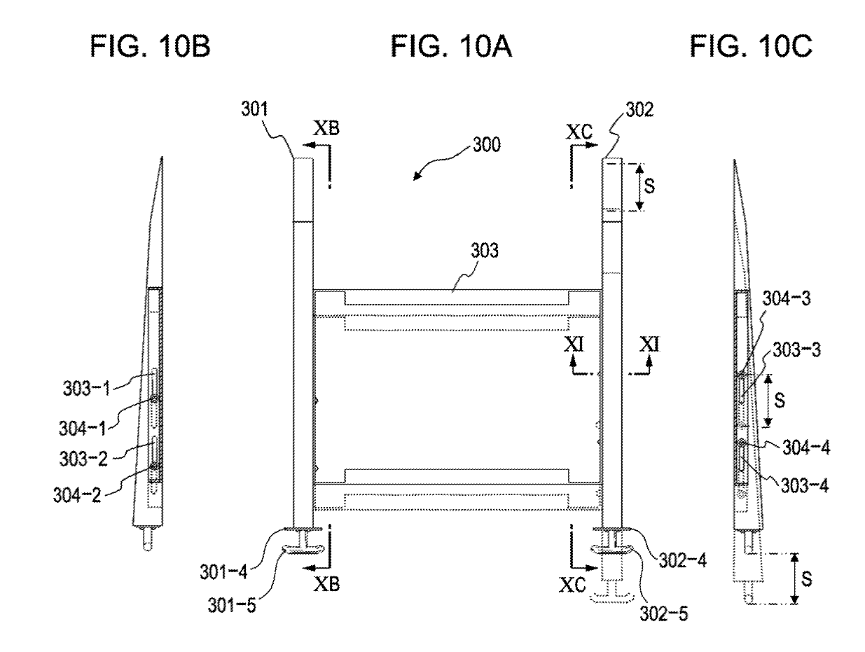

In the installation of the information equipment in the rack, a pair of connection members of the installation jig can be prevented from moving in the width direction of the installation jig, the width direction of the installation jig being vertical to a direction in which the information equipment is installed. The connection members 303 are hereinafter described in detail with reference to FIGS. 10A to 12D.

The end 301-3 of the slidable member 301 has a rectangular stopper 301-4 and a T-shaped knob 301-5, and the end 302-3 of the slidable member 302 also has a rectangular stopper 302-4 and a T-shaped knob 302-5. In the configurations of the stopper 301-4 and knob 301-5, the T-shaped knob 301-5 which is made of metal so as to have rigidity is approximately vertically welded to a surface of the stopper 301-4 which is made of sheet metal so as to have rigidity, and the stopper 301-4 is screwed to the end 301-3 of the slidable member 301. The stopper 301-4 may be screwed to the knob 301-5. Similarly in the configurations of the stopper 302-4 and knob 302-5, the T-shaped knob 302-5 which is made of metal so as to have rigidity is approximately vertically welded to a surface of the stopper 302-4 which is made of sheet metal so as to have rigidity, and the stopper 302-4 is screwed to the end 302-3 of the slidable member 302. The stopper 302-4 may be screwed to the knob 302-5.

In the drawings, the stoppers 301-4 and 302-4 are respectively positioned at heights lower than those of the ends 301-3 and 302-3. Furthermore, the stoppers 301-4 and 302-4 are positioned at heights at which the stoppers 301-4 and 302-4 do not come into collision with the bottom of the equipment that has been pushed to the fore side by being slid on the slidable members 301 and 302. The stoppers 301-4 and 302-4 have protrusions 301-4-1 and 302-4-1 which project to the outside from the outer edges of the ends 301-3 and 302-3, respectively. The protrusions 301-4-1 and 302-4-2 abut on columns inside the rack on which the installation jig 300 is placed or abut on the end surfaces of brackets (not illustrated), thereby preventing the slidable members 301 and 302 from being moved to the fore side during the pushing of the equipment. In addition, the installation jig 300 is configured so as to be positioned at a specific portion of the brackets.

The knobs 301-5 and 302-5 serve to withdraw the installation jig 300 to the near side after the equipment has reached a predetermined position inside the rack.

Description is hereinafter made on the basis of the presumption that the slidable members 301 and 302 of the installation jig 300 are made of a trimmed piece of fluororesin.

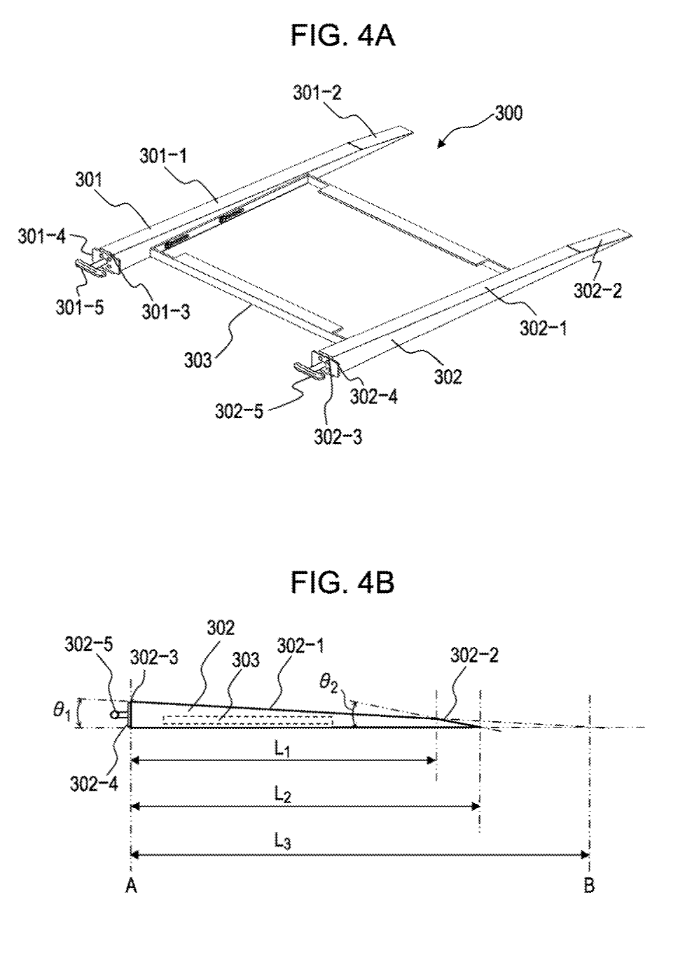

FIGS. 4A and 4B each illustrate an example of the first and second inclined surfaces. FIG. 4A illustrates the appearance of the installation jig 300 viewed from the right-side front thereof. In FIG. 4A, the same numbers as used in FIG. 3A denote the same components. FIG. 4B illustrates the installation jig 300 viewed from the right side. With reference to FIG. 4B, the first inclined surface 302-1 has a tilt angle θ₁ with respect to the horizontal plane and has a length L₁ which extends from a position A of the end 302-3 of the slidable member 302 so as to be parallel to the horizontal plane in a longer direction. The slidable member 302 has the second inclined surface 302-2 at the fore side thereof, and the second inclined surface 302-2 has a length (L₂−L₁) and a tilt angle θ₂ with respect to the horizontal plane. In this case, the tilt angles have relationship of θ₂>θ₁. A virtual extension surface (hereinafter referred to as extension surface, simply) of the first inclined surface 302-1 intersects the horizontal plane at a position B which is distant from the position A in a length L₃. The position B is a home position of the equipment which has been pushed into the rack. In other words, in the case where an end of the bottom of the equipment reaches the position B, the end of the bottom of the equipment intersects the horizontal plane.

The stopper 302-4 is, for example, screwed to the end 302-3 of the slidable member 302, and the T-shaped knob 302-5 is vertically welded to the stopper 302-4. The stopper 302-4 may be screwed to the knob 302-5. In FIG. 4B, the slidable member 301 that forms a pair with the slidable member 302 is hidden by the slidable member 302.

The tilt angle θ₂ of the second inclined surface 302-2 with respect to the horizontal plane is larger than the tilt angle θ₁ of the first inclined surface 302-1 with respect to the horizontal plane. By virtue of such a configuration, the length L₂ of the slidable member 302 can be decreased. Furthermore, in the case where the installation jig 300 is withdrawn, force which acts on the second inclined surface 302-2 can be decreased.

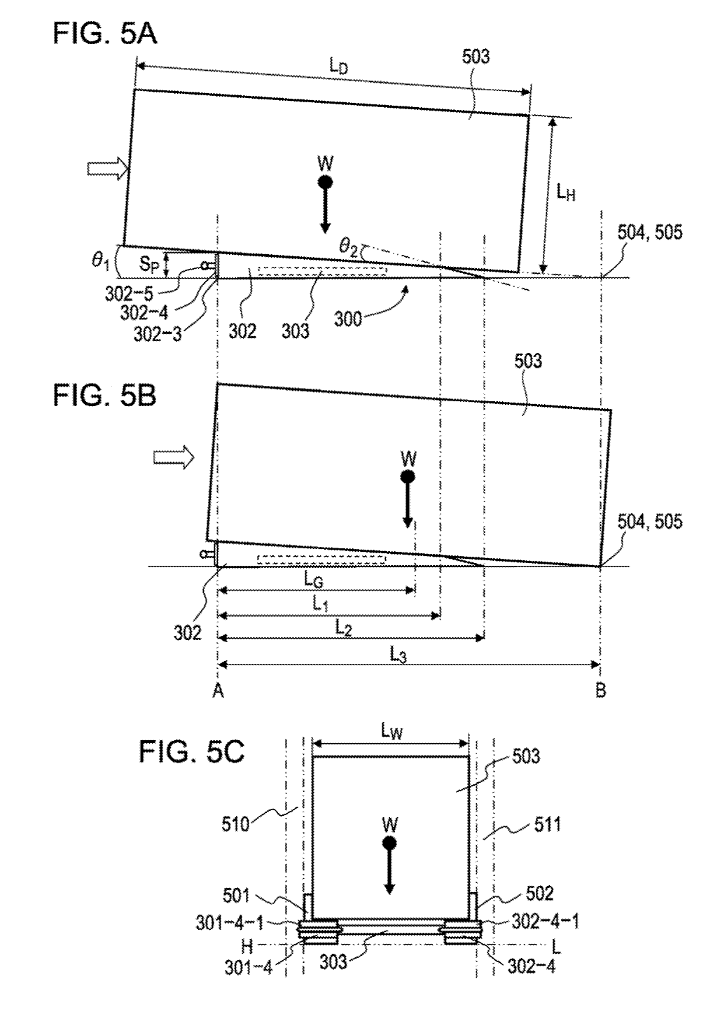

FIGS. 5A to 5C each illustrate an example in which the installation jig of the first embodiment is used. In FIGS. 5A to 5C, the same numbers as used in FIGS. 3A to 4B denote the same components.

FIG. 5A illustrates a state in which the installation jig is used to partway push equipment. FIG. 5B illustrates a state in which the equipment is pushed into a predetermined position. FIG. 5C is a left side view illustrating the state in FIG. 5A.

In FIG. 5A, the respective bottoms 301-10 and 302-10 (not illustrated) of the slidable members 301 and 302 of the installation jig 300 are placed on horizontal surfaces of a pair of L-shaped brackets extending in a direction in which equipment is installed in a rack (hereinafter referred to as surfaces of the L-shaped brackets). For brief and clear illustration, illustration of the rack, inner columns, and L-shaped brackets is omitted in FIGS. 5A and 5B. Inner columns 510 and 511 inside the rack and L-shaped brackets 501 and 502 which are respectively screwed thereto are illustrated in FIG. 5C.

In the drawings from FIG. 5A, the respective bottoms 301-10 and 302-10 of the slidable members 301 and 302 of the installation jig 300 are placed on the surfaces of the pair of the L-shaped brackets having the horizontal surfaces extending in a direction in which the equipment is installed in the rack.

An end of the bottom of equipment 503 having a weight of W kg is placed on the first inclined surfaces 301-1 and 302-1 in the vicinity of the position A with which the near-side end of the installation jig 300 is aligned. External force is applied in a direction indicated by an arrow on the left side in the drawing, thereby sliding the equipment 503 to the right side in the drawing. The first inclined surface 301-1 is hidden by the first inclined surface 302-1 and is therefore invisible in the drawing. With reference to FIG. 5A, the equipment 503 is placed on the installation jig 300 and is tilted at the angle θ₁ with respect to the horizontal plane. The position of the center of gravity of the equipment 503 is represented by the symbol W, and an arrow extending downward from the symbol W indicates a vertical line. The vertical line extending from the center of gravity of the equipment 503 is positioned within the length L1 on the horizontal plane between the position A, at which the end 302-3 of the first inclined surface 302-1 is located, and the other end of the first inclined surface 302-1. In such a state, unless external force is applied to the equipment 503, the equipment 503 does not fall over to the side of the second inclined surface 302-2.

The equipment 503 has an outside dimension of height L_{H}×width L_{w}×length L_{D}. The end 302-3 of the slidable member 302 has a height Sₚ.

FIG. 5B illustrates a state in which the equipment 503 illustrated in FIG. 5A is further pushed to the right side in the drawing with the result that the right end of the bottom of the equipment 503 reaches a predetermined position which is the position B at which the extension surface of the first inclined surface 302-1 intersects the horizontal plane. The position B is located at a distance of the length L3 on the horizontal plane from the position A. The right end of the bottom of the equipment 503 in the drawing abuts on dampers 504 and 505 provided at the position B, thereby stopping at the predetermined position B. The dampers 504 and 505 are respectively provided on surfaces of the L-shaped brackets 501 and 502 so as to be spaced apart from each other at a predetermined distance in a direction vertical to the page of the drawing. The dampers 504 and 505 are made of, for example, a material which absorbs shock, such as rubber or a synthetic resin. In each of the dampers 504 and 505, a member approximately having a length of 20 mm, a width of 20 mm, and a height of 10 mm is screwed so as to protrude upward approximately in a length of 10 mm from the horizontal surface on which the installation jig 300 is placed. Owing to such a configuration, the equipment 503 reaches the predetermined position B and can be then stopped without being subjected to shock. In this case, the dampers 504 and 505 may not be provided, and the configuration in which the equipment 503 moderately abuts on part of each of the inner columns 510 and 511 may be provided in place of the dampers 504 and 505, for example. Any configuration in which the equipment 503 that has reached the predetermined position B can be stopped without being subjected to shock may be sufficiently employed.

In the case where the equipment 503 reaches the position B, the position W of the center of gravity of the equipment 503 exists within a length L_{G} extending from the position A on the horizontal plane and exists within the length L₁ between the position A and the end of the first inclined surface 302-1. The equipment 503 is pushed into a predetermined position, and then a state illustrated in FIG. 5A shifts to a state in which the end of the bottom of the equipment 503 reaches the predetermined position B. Through such a process, the equipment 503 is prevented from falling over to the right side of the first inclined surface 302-1 and is not therefore subjected to shock.

With reference to FIG. 5C, the bottoms of the two slidable members of the installation jig 300 are placed on a pair of the L-shaped brackets 501 and 502 which are attached to the rack (not illustrated) in which the equipment 503 is installed, and the equipment 503 is placed on the first inclined surfaces 301-1 and 302-1. The dampers 504 and 505 illustrated in FIGS. 5A and 5B are respectively screwed to the surfaces of the L-shaped brackets 501 and 502 at positions corresponding to the position B. Meanwhile, in FIGS. 5A and 5B, illustration of the L-shaped brackets 501 and 502 is omitted for brief description. In the case where the equipment 503 is pushed into a predetermined position as illustrated in FIG. 5B, the right end of the bottom of the equipment 503 at the position B has a height the same as those of the surfaces of the L-shaped brackets 501 and 502 on which the bottoms of the slidable members 301 and 302 are respectively placed. The right end of the bottom of the equipment 503 accordingly contacts the L-shaped brackets 501 and 502.

The installation jig 300 has the protrusions 301-4-1 and 302-4-1 which respectively protrude to the outside from the stopper 301-4 and 302-4, and the protrusions 301-4-1 and 302-4-1 respectively abut on the edge surfaces of the inner columns 510 and 511 at the position A. In such a configuration, the slidable members 301 and 302 are prevented from being moved in an anterior direction, the installation jig 300 is set at a specific position on surfaces of the L-shaped brackets 501 and 502, and a relative position of the installation jig 300 with respect to the position B on the surfaces of the L-shaped brackets 501 and 502 is accurately determined.

Use of the installation jig for installing equipment in a rack enables the equipment to be less likely to be subjected to shock and enables the equipment to be slid to a predetermined position inside the rack with further small force. Furthermore, a position on which the installation jig is set can be determined, the unwanted movement of the installation jig to the fore side can be prevented, and force for withdrawing the installation jig to the near side can be decreased. Furthermore, the first inclined surface is formed such that the fore side of the bottom of the equipment which has been pushed into a predetermined position inside the rack is positioned at the height the same as those of surfaces of brackets. By virtue of such a configuration, because the fore side of the bottom of the equipment is prevented from contacting the surfaces of the brackets before the equipment is pushed into a predetermined position inside the rack, the rapid increase of force for pushing the equipment is prevented, and the surfaces of the brackets are not damaged by the fore side of the bottom of the equipment.

In the case of withdrawing the installation jig 300 on which the equipment 503 that has been reached a predetermined position is placed, the knobs 301-5 and 302-5 are utilized to withdraw the installation jig 300 to the near side opposite to a direction in which the equipment 503 is pushed.

In the cases where the installation jig 300 is placed at a specific position on the surfaces of the L-shaped bracket 501 and 502 and where the equipment is then pushed into a predetermined position inside the rack as described above, a phenomenon is prevented, in which the equipment falls over to the fore side in the middle and in which the end of the bottom of the equipment therefore contacts the surfaces of the L-shaped brackets with the result that the equipment is subjected to shock.

Furthermore, positional relationship is provided, in which the end of the bottom of the equipment contacts the surfaces of the L-shaped brackets at a predetermined position of the rack. Owing to such positional relationship, the end of the bottom of the equipment does not contact the surfaces of the L-shaped brackets before the equipment reaches a predetermined position inside the rack, frictional force is not therefore rapidly increased, and the surfaces of the L-shaped brackets are not damaged by the end of the equipment.

Furthermore, because the end of the bottom of the equipment is not separated from the surfaces of the L-shaped brackets at a predetermined position inside the rack, the end of the bottom of the equipment does not collide with the surfaces of the L-shaped brackets during the withdrawing of the installation jig 300 from the equipment, and the equipment is not therefore subjected to shock.

The second inclined surfaces 301-2 and 302-2 are provided, so that the length L₂ of the installation jig 300 can be decreased. Owing to such a configuration, the installation jig 300 can be further easily withdrawn especially after the end of the bottom of the equipment has been positioned on the second inclined surfaces 301-2 and 302-2 during the withdrawing.

In addition to a first inclined surface, a second inclined surface is formed so as to have a larger tilt angle with respect to the horizontal plane relative to the tilt angle of the first inclined surface with the result that the total lengths of the slidable members can be decreased. The installation jig can be therefore easily withdrawn with the result that the number of operational processes can be decreased. In addition, in the case where the installation jig is withdrawn from the equipment, the fore side of the bottom of the equipment can be prevented from swiftly contacting the surfaces of the brackets with the result that shock which acts on the equipment can be suppressed.

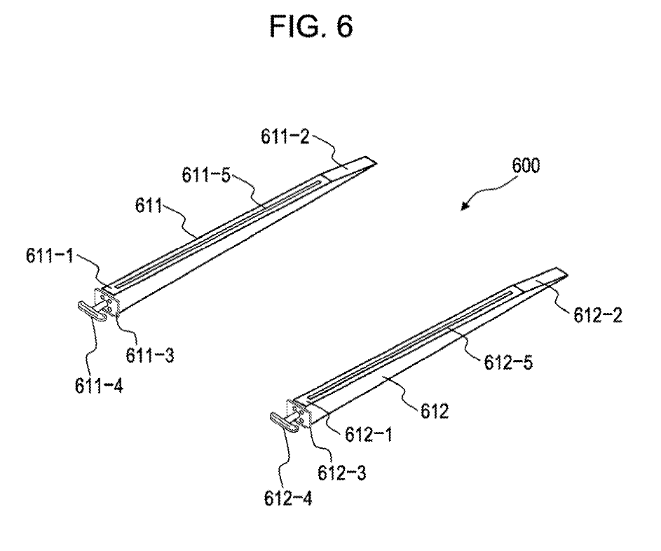

FIG. 6 illustrates another example of the first inclined surface. In an installation jig 600, a pair of slidable members 611 and 612 have first inclined surfaces 611-1 and 612-1 having partially uneven portions and have grooves 611-5 and 612-5 in a longer direction, respectively. Equipment is slid on the first inclined surfaces 611-1 and 612-1, and it is therefore preferable that the first inclined surfaces 611-1 and 612-1 partially have even portions which extend in a longer direction. In addition, it is preferable that the first inclined surfaces 611-1 and 612-1 do not have irregular portions which extend in a longer direction and which therefore prevent the smooth sliding of the equipment. The slidable members 611 and 612 have second inclined surfaces 611-2 and 612-2, stoppers 611-3 and 612-3, and knobs 611-4 and 612-4, respectively.

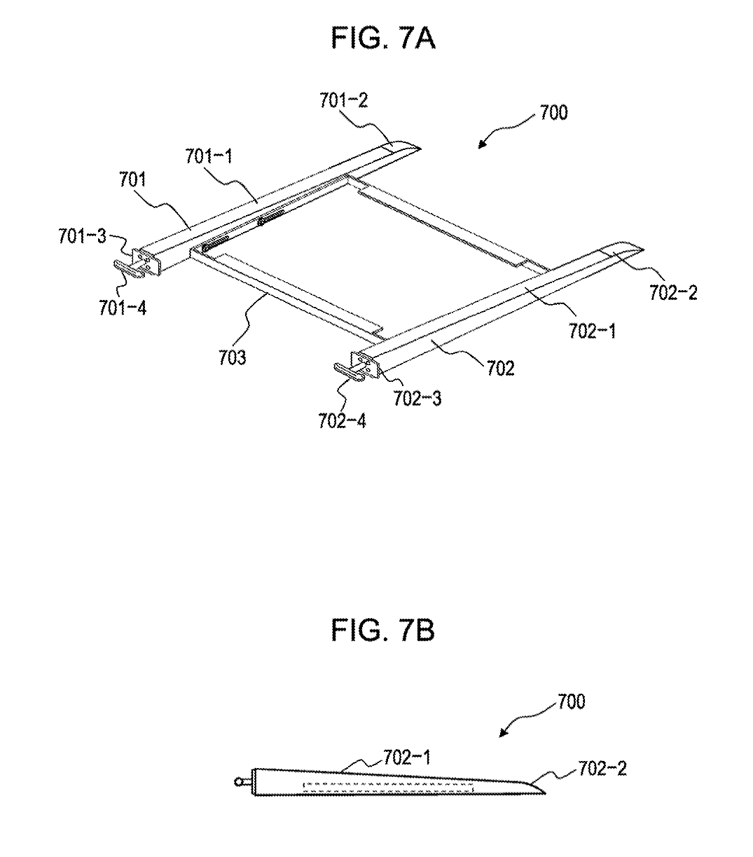

FIGS. 7A and 7B each illustrate another example of the second inclined surface. FIG. 7A illustrate the appearance of an installation jig 700 viewed from the right-side front thereof. FIG. 7B illustrates the installation jig 700 viewed from the right side. The slidable members 701 and 702 of the installation jig 700 have first inclined surfaces 701-1 and 702-1 and second inclined surfaces 701-2 and 702-2 extending from the first inclined surfaces 701-1 and 702-1, respectively. The second inclined surfaces 701-2 and 701-2 have non-linear surfaces which are curved so as to form smoothly-raised structure. In the case of withdrawing the installation jig 700 from equipment which has been pushed into a predetermined position inside a rack, the near-side end of the bottom of the equipment is slid on the first inclined surfaces 701-1 and 702-1 and is then slid on the second inclined surfaces 701-2 and 702-2. Any configuration which enables the installation jig 700 to be withdrawn such that the equipment is not subjected to shock can be sufficiently employed. The slidable members 701 and 702 further have stoppers 701-3 and 702-3 and knobs 701-4 and 702-4 in addition to the first inclined surfaces 701-1 and 702-1 and are connected through connection members 703, respectively.

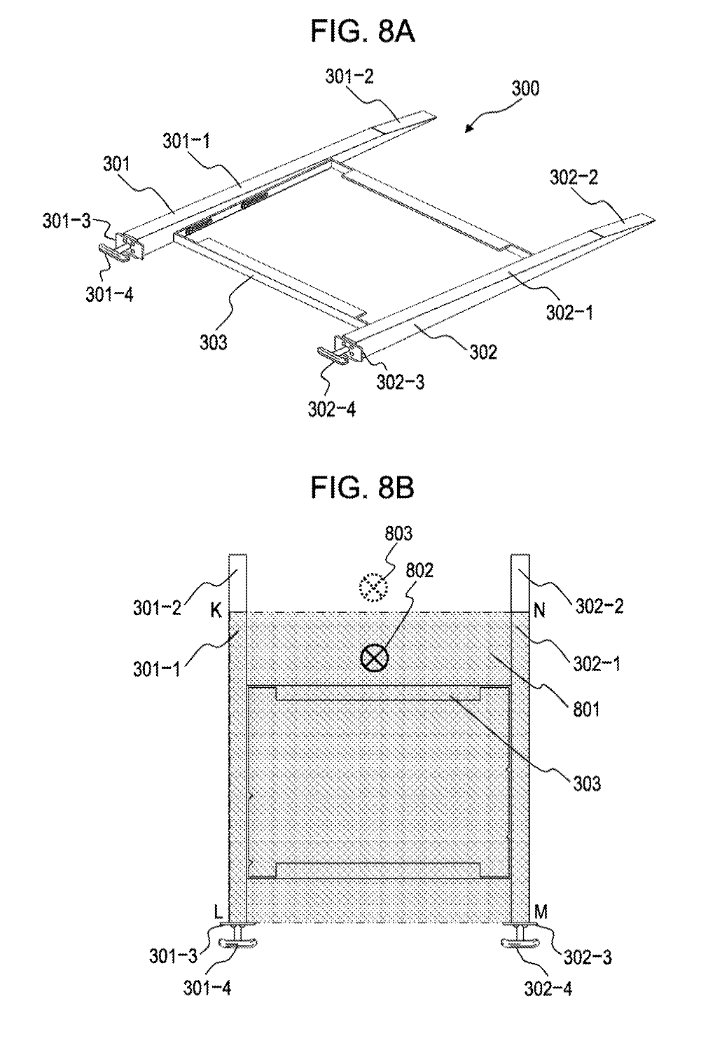

FIGS. 8A and 8B each illustrate an example of an inter-inclined surface region which is a minimum rectangular region including a pair of first inclined surfaces.

FIG. 8A illustrates the appearance of the installation jig 300 viewed from the right-side front thereof. In the FIG. 8A, the same numbers as used in FIG. 4A denote the same components. FIG. 8B illustrates the installation jig 300 viewed from the upper side of a pair of the first inclined surfaces 301-1 and 302-1. In the installation jig 300, an inter-inclined surface region which is a minimum rectangular region including a pair of the first inclined surfaces 301-1 and 302-1 refers to a rectangular region 801 which is surrounded by two outer ends K and L of the first inclined surface 301-1 and two outer ends M and N of the first inclined surface 302-1. In the case where a vertical line extending from the position of the center of gravity of equipment is positioned so as to intersect the inter-inclined surface region, a mark 802 indicates a point of intersection between such a vertical line and the inter-inclined surface region. In the case where the vertical line extending from the position of the center of gravity of the equipment is positioned so as not to intersect the inter-inclined surface region, a mark 803 indicates such a position.

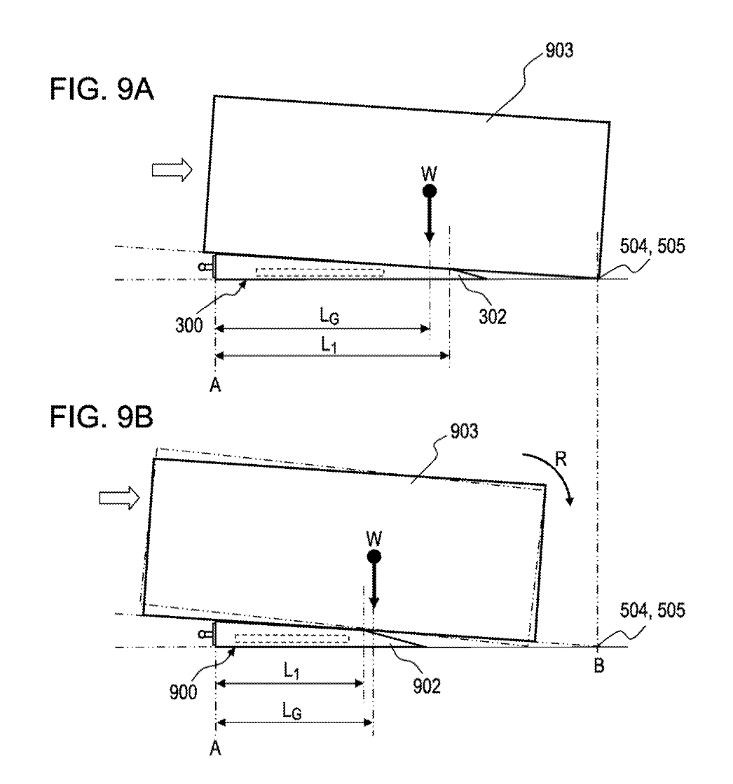

FIGS. 9A and 9B each illustrate relationship between the vertical line extending from the position of the center of gravity of the equipment and the inter-inclined surface region.

FIG. 9A illustrates a state in which the equipment is sufficiently pushed into a home position. FIG. 9B illustrates a state in which the equipment is not sufficiently pushed into a home position. In FIG. 9A, the same numbers as used in FIGS. 5A to 5C and 8A and 8B denote the same components.

With reference to FIG. 9A, equipment 903 is pushed and slid on the installation jig 300, and an end of the bottom of the equipment 903 then reaches the position B as the home position. In a state in which the end of the bottom of the equipment 903 has reached the position B at which the dampers 504 and 505 are provided, the vertical line extending from the center of gravity W of the equipment 903 is positioned at a distance L_{G} extending from the position A on the horizontal plane. During the sliding of the equipment 903 on the first inclined surface 302-1 of the installation jig 300, the equipment 903 does not fall over and therefore does not collide with surfaces of the L-shaped brackets on which the bottom of the slidable member 302 is placed. In this case, relationship of L₁>L_{G} is provided. In addition, such a case corresponds to the case indicated by the mark 802 in FIG. 8B.

In contrast, with reference to FIG. 9B, respective first inclined surfaces 901-1 and 902-2 of a pair of slidable members 901 and 902 of an installation jig 900 have the shorter lengths L₁ in a longer direction on the horizontal plane relative to the lengths L₁ in FIG. 9A. In the case where the vertical line extending from the position of the center of gravity of equipment 903 is positioned on the right side from the L₁ in the drawing, the equipment 903 falls over in an R direction at the time that relationship of L_{G}>L₁ is generated in the middle of pushing the equipment 903 to the home position. The bottom of the equipment 903 collides with the surfaces of the brackets with the result that the equipment 903 is subjected to shock, and sliding resistance is rapidly increased. Such a case corresponds to the case indicated by the mark 803 in FIG. 8B. In such a state, further large pushing force is needed to push the equipment 903 into the position B as a predetermined position, and the surfaces of the brackets are damaged.

The equipment 903 therefore needs to be prevented from falling onto the surface of the bracket before the equipment 903 reaches a predetermined position as illustrated in FIG. 9B, thereby preventing the equipment 903 from being subjected to shock. Damage of components inside the equipment 903 and the increase of pushing force accordingly need to be prevented.

FIGS. 10A to 10C each illustrate components of the installation jig of the first embodiment. In FIGS. 10A to 10C, the same numbers as used in FIGS. 3A and 3B denote the same components. In FIGS. 10B and 10C, the connection members 303 have elongate holes 303-1 to 303-4 each having a length S/2 and serve to connect the slidable member 301 to the slidable member 302 with screws 304-1 to 304-4.

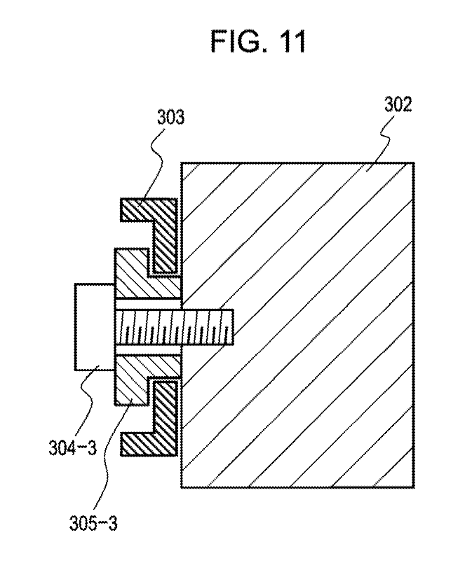

FIG. 11 is a cross-sectional view illustrating the installation jig of the first embodiment taken along the line XI-XI in FIG. 10A and illustrates the installation jig in detail. The connection member 303 is attached to the slidable member 302 through a collar 305-3 with a flange by using the screw 304-3. The connection member 303 is interposed between an edge of the slidable member 302 and an edge of the flange of the collar 305-3, and a distance therebetween is approximately 0.5 mm larger than the thickness of the connection member 303, thereby preventing the connection member 303 from being completely fixed to the slidable member 302 with the screw 304-3. In this case, the connection member 303, collar 305-3, and screw 304-3 are made of, for example, mild steel. The cross-sectional surfaces of other screwed portions in FIGS. 10A to 10C have the configurations the same as above. The connection members 303 are accordingly regulated so as to form a distance of at most 1 mm from each of the slidable members 301 and 302 in FIGS. 10A to 10C, and the connection members 303 can be moved in a vertical direction in the drawings.

Returning to FIGS. 10A to 10C, the slidable members 301 and 302 are set at a full position on the top side in the drawing with respect to the connection members 303. In the case where the slidable member 302 is moved to the bottom side in the drawings, the slidable member 302 can be moved to the bottom side in a length of S mm which is approximately twice as long as the length of each of the elongate holes 303-1 to 303-4. In the case where the slidable member 301 is then moved to the bottom side in the drawings, the slidable member 301 can be moved to the bottom side in a length of S mm which is approximately twice as long as the length of each of the elongate holes 303-1 to 303-4. The slidable members 301 and 302 are configured, for example, so as to be alternately withdrawn in a maximum relative stroke S of approximately 90 mm. Such a length is approximately twice as long as the lengths of the elongate holes 303-1 to 303-4 of the connection members 303.

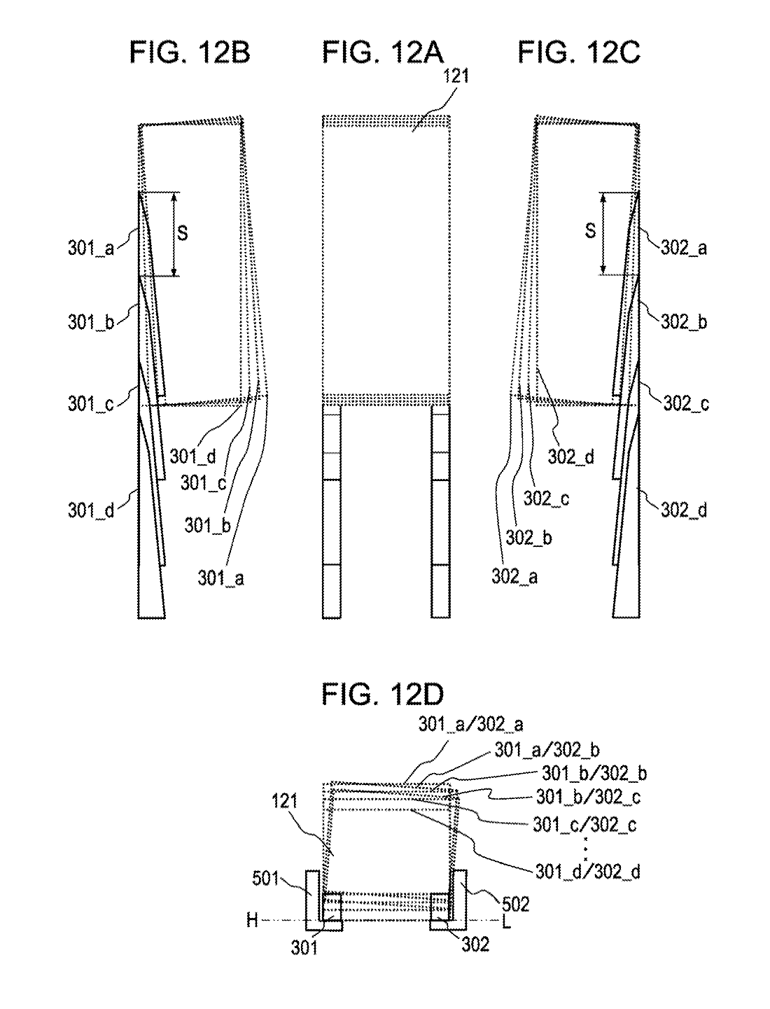

FIGS. 12A to 12D each illustrate the operation of the installation jig of the first embodiment. FIG. 12A is a top view illustrating the installation jig 300 during being withdrawn. FIG. 12B is a left side view illustrating the installation jig 300 in such a state, FIG. 12C is a right side view illustrating the installation jig 300 in such a state, and FIG. 12D is an elevational view illustrating the installation jig 300 in such a state. The L-shaped brackets 501 and 502 are positioned on the horizontal plane indicated by the line H-L, and the bottoms of the slidable members 301 and 302 are respectively positioned on the surfaces of the L-shaped brackets 501 and 502.

After equipment 121 has been pushed into a predetermined position, the slidable members 301 and 302 are alternately withdrawn in the length of S mm to the near side which is opposite to a direction in which the equipment 121 is pushed, the length of S mm being twice as long as the lengths of S/2 mm of the elongate holes 303-1 to 303-4 which are provided to the connection members 303 as illustrated in FIGS. 10A to 10C. The slidable members 301 and 302 on which the equipment 121 is placed are alternately withdrawn in a movable stroke of S mm, thereby generating difference in height between the slidable members 301 and 302. The equipment 121 therefore tilts to the right and left sides as illustrated in FIGS. 12A to 12D.

In FIGS. 12A to 12D, the symbols 301_{—}a to 301_{—}d indicate transition of the position of the slidable member 301 when the slidable member 301 is withdrawn from the initial state 301_{—}a in the length of S mm in stages. The symbols 302_{—}a to 302_{—}d indicate transition of the position of the slidable member 302 when the slidable member 302 is withdrawn from the equipment 121 which has been pushed into a predetermined position, the slidable members 302 being withdrawn from the initial state 302_{—}a in the length of S mm in stages.

The slidable member 302 is first withdrawn from the equipment 121 in a length of S mm, and the slidable member 302 is moved to a position 302_{—}b. In FIG. 12D, the equipment 121 which is in an initial state 301_{—}a/302_a and does not tilt to the right and left sides enters a state 301_{—}a/302_b in which the equipment 121 tilts to the right side. In this state, the slidable member 301 is further withdrawn from the equipment 121 in a length of S mm, and the slidable member 301 is then moved to a position 301_{—}b. In this case, the slidable member 302 is still located at the position 302_{—}b, and the equipment 121 therefore enters a state 301_{—}b/302_b in which the equipment 121 does not tilt to the right and left sides.

Such processes are repeated, the slidable member 302 reaches a position 302_{—}d, and the slidable member 301 reaches a position 301_{—}d. In such a state, the equipment 121 is separated from the installation jig 300. During such an operation, the equipment 121 shifts from the sate 301_{—}a/302_a to states 301_{—}a/302_b, 301_{—}b/302_b, 301_{—}b/302_c, 301_{—}c/302_c, 301_{—}c/302_d, 301_{—}d/302_d in stages. Meanwhile, illustration of the stoppers 301-4 and 302-4 and knobs 301-5 and 302-5 is omitted.

In the installation jig 300 having the connection members 303, the lengths of S/2 mm of the elongate holes 303-1 to 303-4 provided to the connection members 303 as illustrated in FIGS. 10A to 10C are preliminarily defined, and the slidable members 301 and 302 are individually withdrawn in stages. The stroke S is appropriately selected, and the tilt of the equipment 121 to the right and left sides is suppressed to prevent the falling of the equipment 121, thereby being able to easily withdraw the installation jig 300.

In FIGS. 12A to 12D, assuming that the slidable members 301 and 302 are alternately withdrawn in a stroke S of 90 mm and that the first inclined surface of each of the slidable members 301 and 302 tilts at an angle θ₁ of 3° with respect to the horizontal plane, difference H mm in the height of the equipment 121 between the left side and the right side in FIG. 12D can be obtained from the following formula, the equipment 121 being placed on the slidable members 301 and 302.

H=S×tan 3°≈4.72 mm

Assuming that the equipment 121 has a width L_{W} of 440 mm, the tilt angle θ of the equipment 121 to the right and left sides is obtained from the following formula.

θ≈0.61° is obtained from sin θ=H/L_{W}

As described above, the movable stroke (S mm) of the slidable members and the angle of the first inclined surface with respect to the horizontal plane have an influence on the tilt angle θ of the equipment. In the case of a large tilt angle θ, the equipment may contact the inner columns inside the rack. In view of such a problem, the slidable members 301 and 302 of the installation jig 300 needs to be able to be moved in a stroke which enables the equipment to be prevented from contacting the inner columns inside the rack.

As described above, the slidable members 301 and 302 of the installation jig 300 is connected by the connection members 303 and can be alternately withdrawn in a predetermined stroke in a direction opposite to a direction in which the equipment is pushed. As compared with the case in which the slidable members 301 and 302 are simultaneously withdrawn, the slidable members 301 and 302 can be withdrawn with small force. In addition, the stroke is limited, thereby suppressing the tilt of the equipment to the right and left sides with the result that the equipment can be prevented from contacting the columns inside the rack.

The slidable members are individually withdrawn in a predetermined stroke. In the case of withdrawing the installation jig from information equipment with heavy weight, the installation jig is therefore allowed to be withdrawn with force approximately half the magnitude of the force with which the slidable members are simultaneously withdrawn.

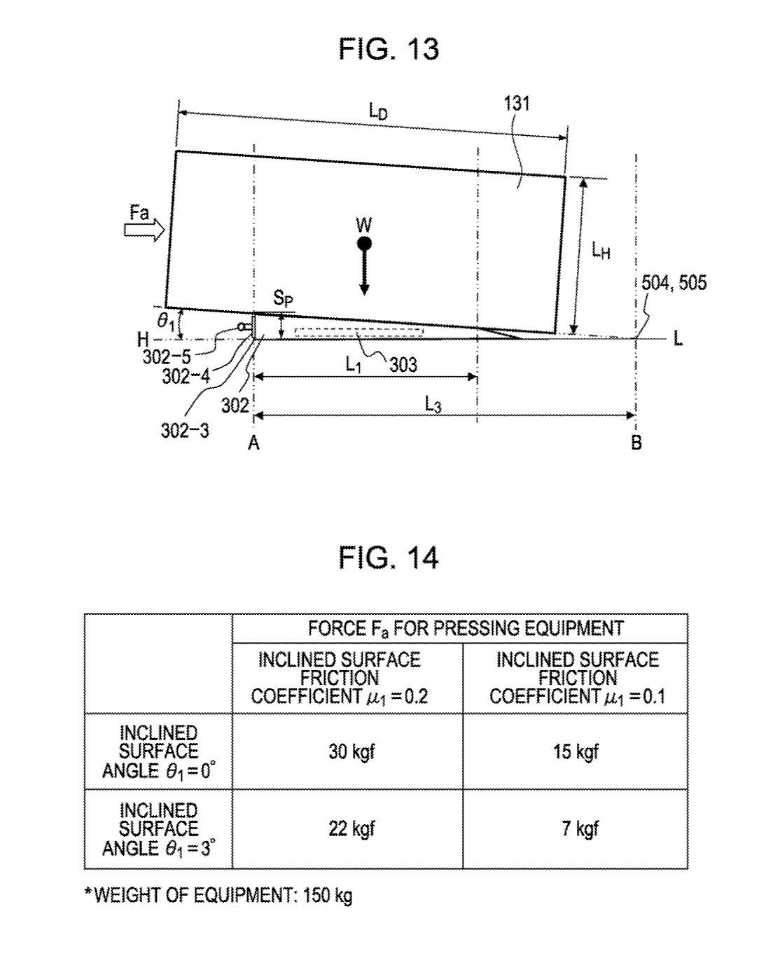

FIG. 13 illustrates force for pushing equipment with the installation jig. Force for pushing equipment 131 into a predetermined position inside the rack by using the installation jig 300 is described. In FIG. 13, the same numbers as used in FIGS. 4A and 4B denote the same components.

Merely in view of a friction coefficient, for example, a sliding surface (not illustrated) including ball bearings, roller bearings, or the likes may be employed as the first inclined surface 301-1 and bottom 301-10 of the slidable member 301 and as the first inclined surface 302-1 and bottom 302-10 of the slidable member 302. In this case, although a friction coefficient can be reduced to a level of approximately 0.01 or lower, the following problems arise.

The first inclined surface 302-1 has a slight tilt angle, and the equipment 131 therefore slides off on the first inclined surface 302-1 resulting from its own weight and then stops by colliding with the damper 505. The right end of the bottom of the equipment 131 accordingly strikes against surfaces of the L-shaped brackets. In such a case, the equipment 131 has high possibility of being subjected to shock.

If the bearings are used to support the equipment 131, the equipment 131 is supported by small areas of the bearings with high density. The bottom of the equipment 131 therefore needs to have toughness sufficient to accept such supporting, and the equipment 131 needs to have a smooth bottom which contacts the bearings.

In place of using the ball bearings, roller bearings, or the likes, a slidable member including an inclined surface or bottom each having an appropriate friction coefficient is preferably employed as a low friction coefficient member. In order to tilt and then push the equipment 131 into the rack, a tilt space height Sₚ which serves to tilt the equipment 131 in a state in which the rear side (left side in the drawing) of the equipment 131 is lifted needs to be secured in a height direction inside the rack. In a rack in which several pieces of equipment are installed with high density, such as a data center, a small tilt space height Sₚ is preferably employed, and a tilt space height Sₚ which is less than or equal to 1U (height: 44.45 mm) that is the minimum unit of an accommodation slot in a 19 inch rack is employed.

A tilt angle of the installation jig 300 which satisfies the tilt space height Sₚ that is less than or equal to 1U is described. Assuming that the equipment 131 has a total length L_{D} of 800 mm, the tilt angle θ₁ of the first inclined surface which enables the tilt space height Sₚ that is less than or equal to 1U (44.45 mm) is obtained from the following formula. In this case, relationship of θ₁≦3.1° is assumed.

800 (mm)×sin θ₁≦44.45 (mm)

As is obvious from the drawing, the larger the θ1 becomes, the more force for pushing the equipment 131 decreases. For the above reason, however, the relationship of θ₁≦3.1° is employed.

In addition, the lower the friction coefficient μ₁ of the first inclined surface 302-1 (tan ρ₁=μ₁, in this case, ρ₁ is a friction angle, and such an angle refers to an angle at which the equipment 131 naturally begins to slide when the angle of the first inclined surface 302-1 with respect to the horizontal plane is increased from 0°) becomes, the more force for pushing the equipment 131 decreases.

However, in the case where a friction coefficient is decreased with the result that relationship of ρ₁≦θ₁ is generated, the equipment 131 naturally slips into the inside of the rack. Shock at the time of the collision of the equipment 131 at a predetermined position therefore becomes problematic. Another problem also arises in safety of installing operation. The relationship of ρ₁>θ₁ therefore needs to be secured as a condition which enables the equipment 131 to be prevented from naturally slipping and then falling. In order to secure the above relationship of θ₁≦3.1° and ρ₁>θ₁, for example, a friction coefficient of 0.053 or larger is needed in the case of relationship of θ₁=3°, and a friction coefficient of 0.035 or larger is needed in the case of relationship of θ₁=2°.

In contrast, the more the θ₁ decreases with respect to ρ₁, the more force for pushing the equipment increases. Load on users are therefore increased.

In view of the above requirement, conditions which enable the pushing force to be appropriately decreased such that the relationship of θ₁≦3.1° and ρ₁>θ₁ is satisfied need to be provided in the installation jig 300. Because the height of the equipment 131 is limited, the range of θ₁ is limited. In the case of small ρ₁, the shock to the equipment becomes problematic, and in the case of large ρ₁, the increase of pushing force becomes problematic. These problems are needed to be dissolved. The pushing force Fₐ is represented by the following formula.

Fₐ=W×tan(ρ₁−θ₁) formula 1

In this case, relationship of tan ρ₁=μ₁ is assumed. Furthermore, μ₁ represents a friction coefficient between the first inclined surface 302-1 and the bottom of the equipment 131, ρ₁ represents a friction angle between the first inclined surface 302-1 and the bottom of the equipment 131, and θ₁ represents a tilt angle of the first inclined surface 302-1 with respect to the horizontal plane.

In the case of relationship of θ₁>θ₁′, assuming that Fₐ represents pushing force in the case of θ₁ and that Fₐ′ represents pushing force in the case of θ₁′, relationship of Fₐ<Fₐ′ is obtained from the formula 1.

In the case of relationship of μ₁<μ₁′, assuming that Fₐ represents pushing force in the case of μ₁ and that Fₐ′ represents pushing force in the case of μ₁′, relationship of Fₐ<Fₐ′ is obtained from the formula 1.

FIG. 14 illustrates relationship between force for pushing equipment with the installation jig and the first inclined surface.

In this case, the equipment 131 has a weight W of 150 kg, a tilt angle of the first inclined surface with respect to the horizontal plane is θ₁, the pushing force in a horizontal direction is Fₐ, and a friction coefficient between the bottom of the equipment 131 and each of the first inclined surfaces 301-1 and 302-1 is μ₁.

Assuming that the tilt angle θ₁ is 0° and 3° and that the friction coefficient μ₁ between the bottom of the equipment 131 and the first inclined surface 302-1 is 0.2 and 0.1, an example is described on the basis of the formula 1.

In the cases where the μ₁ is 0.2 and 0.1 and where the installation jig 300 is not used, the force Fₐ for pushing the equipment is 30 kgf and 15 kgf, respectively.

In contrast, in the cases where the installation jig 300 is used and where the tilt angle θ₁ is 3°, Fₐ is 22 kgf at the μ₁ of 0.2, and Fₐ is 7 kgf at the μ₁ of 0.1.

In other words, an angle of 3° is formed between the first inclined surface 302-1 and the horizontal plane, and fluororesin having a friction coefficient of 0.1 is employed as a material of the entire slidable member 302 on which the steel bottom of the equipment 131 is slid, thereby being able to provide relationship of Fₐ=7 kgf.

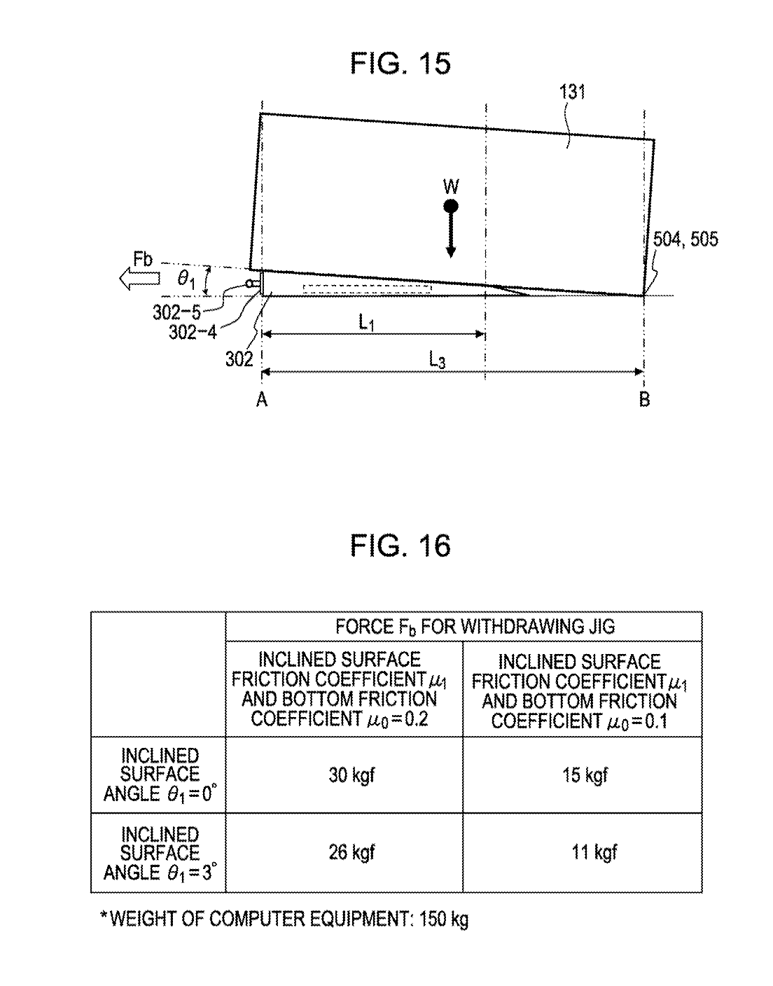

FIG. 15 illustrates force for withdrawing the installation jig.

withdrawing force F_{b}=(½)W[tan(ρ₁−θ₁)+tan ρ₀] formula 2

In this case, relationship of tan ρ₁=μ₁ is assumed, and relationship of tan ρ₀=μ₀ is assumed. Furthermore, μ₁ represents a friction coefficient between the first inclined surface 302-1 and the bottom of the equipment 131, μ₀ represents a friction coefficient between the bottom 302-10 and a surface of the L-shaped bracket, ρ₁ represents a friction angle between the first inclined surface 302-1 and the bottom of the equipment 131, ρ₀ represents a friction angle between the bottom 302-10 and a surface of the L-shaped bracket, and θ₁ represents a tilt angle of the first inclined surface 302-1 with respect to the horizontal plane. The weight W is dispersed to the slidable members 301 and 302, and each of the slidable members 301 and 302 therefore has a weight of (½)×W.

In the case of relationship of θ₁>θ₁′, assuming that F_{b} represents withdrawing force at the tilt angle θ₁ and that F_{b}′ represents withdrawing force at the tilt angle θ₁′, relationship of F_{b}<F_{b}′ is obtained from the formula 2.

In the cases of relationship of μ₁<μ₁′ and relationship of μ₀<μ₀′, assuming that F_{b} represents withdrawing force at the friction coefficients μ₁ and μ₀ and that F_{b}′ represents withdrawing force at the friction coefficients μ₁′ and μ₀′, relationship of F_{b}<F_{b}′ is obtained from the formula 2.

In the cases where the equipment 131 is pushed and where the fore-side end of the equipment 131 reaches the position B as a predetermined position, the fore-side end of the bottom of the equipment 131 is positioned at the height the same as those of surfaces of the L-shaped brackets. By virtue of such a configuration, in the case where the installation jig 300 is withdrawn, the fore-side end of the bottom of the equipment 131 can be prevented from striking against the surfaces of the L-shaped brackets. Furthermore, although not illustrated, in the case where the installation jig 300 is withdrawn from the equipment 131, the left-side end of the equipment 131 in the drawing is temporarily fixed to a fixing member inside the rack by using, for example, screws, thereby preventing the movement of the equipment 131 to the left side in the drawing.

The first inclined surface 302-1, second inclined surface 302-2, bottom 302-10 of the slidable member 302 have an effect on force for withdrawing the installation jig. In this case, although the decrease of the friction coefficient leads to the decrease of the withdrawing force, the installation jig moves forward resulting from the weight of the equipment 131 in the case where the friction coefficient is decreased with the result that relationship of tan(ρ₁−θ₁)+tan ρ₀<0 and tan(ρ₂−θ₂)+tan ρ₀<0 is generated. Problems therefore arise in safety. In this case, ρ₁, ρ₂, and ρ₀, represent a function (tan ρ=μ) relating the friction coefficients of the first inclined surface, second inclined surface, and bottom, respectively. Furthermore, θ₂ represents an angle of the second inclined surface with respect to the horizontal plane.

In order to prevent the installation jig from moving forward only resulting from the weight of computer equipment, conditions of both tan(ρ₁−θ₁)+tan ρ₀>0 and tan(ρ₂−θ₂)+tan ρ₀>0 need to be satisfied. In such conditions, θ₁, ρ₁, ρ₂, and θ₂ need to be determined. As in the case of the first inclined surface, for example, in the case where a fluororesin material having a friction coefficient of 0.1 is employed as a material of the second inclined surface, the above conditions can be satisfied as a result of forming an inclined surface angle θ₂ of 11.4° or smaller.

By virtue of such a configuration, the length of the fore side of the installation jig 300 can be decreased. In addition, in the case where the installation jig 300 is withdrawn, force which acts on the second inclined surface can be decreased.

FIG. 16 illustrates relationship between force for withdrawing the installation jig and the first inclined surface on the basis of illustration in FIG. 15. The force F_{b} for withdrawing the installation jig 300 is obtained from the formula 2. In an example, assuming that the equipment 131 has a weight W of 150 kg and that the first inclined surface 302-1 forms angles θ₁ of 0° and 3° with respect to the horizontal plane, a friction coefficient μ₁ between the first inclined surface 302-1 and the bottom of the equipment 131 is 0.2, and a friction coefficient μ₀ between the bottom 302-10 and surfaces of the L-shaped brackets is 0.2. Furthermore, in another example, assuming that the first inclined surface 302-1 forms angles θ₁ of 0° and 3° with respect to the horizontal plane, a friction coefficient μ₁ between the first inclined surface 302-1 and the bottom of the equipment 131 is 0.1, and a friction coefficient μ₀ between the bottom 302-10 and surfaces of the L-shaped brackets is 0.1.

The example in which relationship of θ₁=0° and relationship of μ₁=μ₀=0.2 are provided corresponds to the case in which the installation jig 300 is not used. The example in which relationship of θ₁=3° and relationship of μ₁=μ₀=0.1 are provided corresponds to the case in which the installation jig 300 is used as illustrated in FIG. 15. In this case, the installation jig 300 can be withdrawn with a force F_{b} of 11 kgf.

Accordingly, for example, an installation jig is used, in which an angle of 3° is formed between the first inclined surface 302-1 and the horizontal plane and in which a fluororesin material having a friction coefficient of 0.1 is employed as a material of the slidable member 302 on which the steel bottom of the equipment 131 is slid. By virtue of such a configuration, the equipment 131 can be easily pushed into a home position inside the rack, and the installation jig can be then easily withdrawn from such a home position inside the rack.

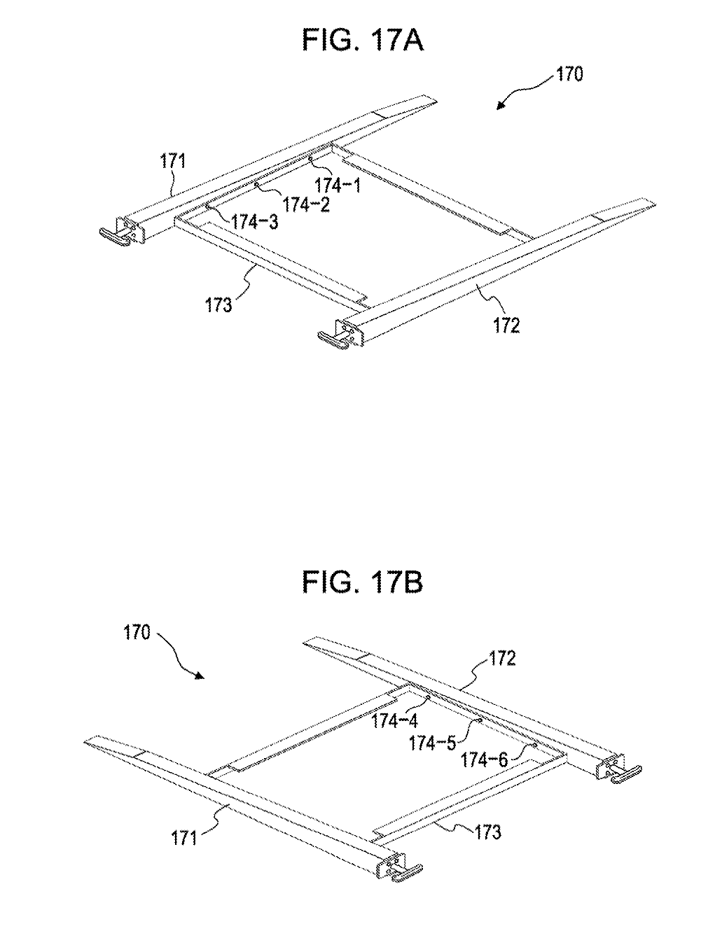

FIGS. 17A and 17B each illustrate an installation jig of a second embodiment. FIG. 17A illustrates the appearance of an installation jig 170 viewed from the right-side front thereof. FIG. 7B illustrates the appearance of the installation jig 170 viewed from the left-side front thereof. The installation jig 170 of the second embodiment has slidable members 171 and 172 which are fixed to connection members 173 with screws 174-1 to 174-3 and 174-4 to 174-6, respectively. Unlike the installation jig 300, the slidable members 171 and 172 are fixed to the connection members 173. In the case where the installation jig 170 is withdrawn from equipment, the slidable members 171 and 172 are withdrawn at the same time. Although withdrawing force twice as large as force for individually withdrawing slidable members 171 and 172 is needed, equipment to be installed can be prevented from tilting to the left and right sides. The installation jig 170 is appropriately used for installing equipment having a weight smaller than that of the equipment to be installed by using the installation jig 300.

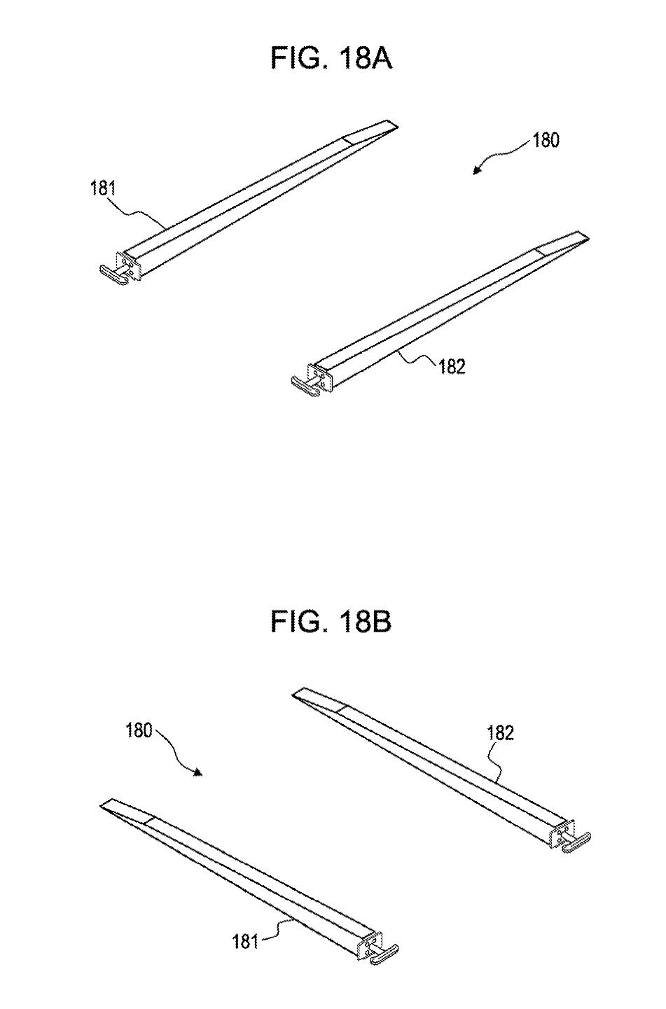

FIGS. 18A and 18B each illustrate an installation jig of a third embodiment. FIG. 18A illustrates the appearance of an installation jig 180 viewed from the right-side front thereof. FIG. 18B illustrates the appearance of the installation jig 180 viewed from the left-side front thereof. In the installation jig 180 of the third embodiment, a connection member that serves to connect slidable member 181 to slidable member 182 is not used, and the configurations of the installation jigs 300 and 170 are further simplified. The installation jig 180 is appropriately used for installing equipment having a weight further smaller than that of the equipment to be installed by using the installation jigs 300 and 170.

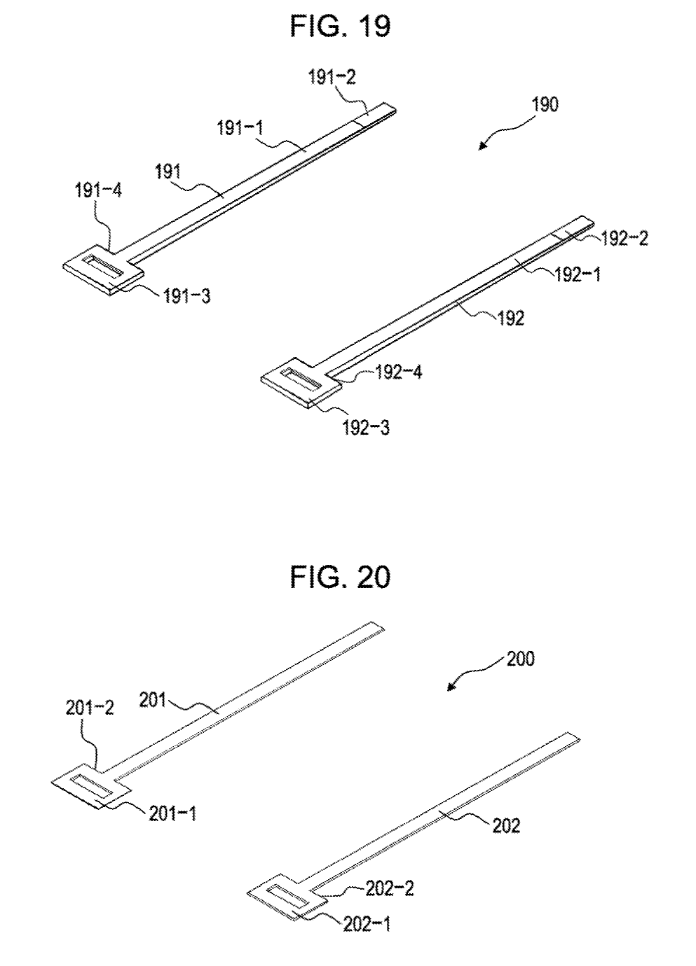

FIG. 19 illustrates an installation jig of a fourth embodiment. An installation jig 190 is made from, for example, fluororesin. In the installation jig 190, a slidable resin 191 has a first inclined surface 191-1 and a second inclined surface 191-2 and has a knob 191-3 and a stopper 191-4 each being integrated with the slidable member 191. In addition, a slidable member 192 has first inclined surface 192-1 and a second inclined surface 192-2 and has a knob 192-3 and a stopper 192-4 each being integrated with the slidable member 192. The installation jig 190 is therefore easily manufactured. The installation jig 190 is appropriately used for installing equipment having a weight further smaller than that of the equipment to be installed by using the installation jig 180.

The slidable members, stoppers, and knobs are formed so as to be respectively integrated in the form of continuous sheets, and the installation jig is therefore easily manufactured.

FIG. 20 illustrates an installation jig of a fifth embodiment. An installation jig 200 includes sheet-like slidable members 201 and 202. The slidable members 201 and 202 each have a first inclined surface having a tilt angle of approximately 0°. The installation jig 200 is further easily manufactured as compared with the installation jig 190. The installation jig 200 is appropriately used for installing equipment having a weight further smaller than that of the equipment to be installed by using the installation jig 190. In this case, the installation jig 200 preferably has a thickness smaller than those of surfaces of L-shaped brackets. Because the installation jig 200 does not have first inclined surfaces, the bottom of the fore side of equipment which has been pushed for installation and which has then reached a predetermined position does not contact the surfaces of the L-shaped brackets. In this state, a height corresponding to the thickness of each of the slidable members 201 and 202 is therefore generated between the equipment and the surfaces of the L-shaped brackets. The installation jig 200 is withdrawn from the equipment in this state, and then the bottom of the fore side of the equipment may collide with the surfaces of the L-shaped brackets. Furthermore, tension strength needs to be secured across the installation jig 200. The full body of the installation jig 200 is formed, for example, as follows: stainless steel having a thickness of approximately 1 mm is used to form a cored bar; and fluororesin sheets each having a thickness of approximately 1 mm are attached to the top and rear surfaces thereof. In this case, for example, the stainless steel has a tensile strength of 520 N/mm², and the fluororesin sheet has a tensile strength that is in the range from 13.7 to 34.3 N/mm². In such a case, each of the slidable members 201 and 202 has a reduced thickness, for example, and tapers each having an angle that is in the range from 30° to 60° are therefore formed at the fore-side ends of the slidable members 201 and 202. By virtue of such a configuration, in the case where the installation jig 200 is withdrawn from equipment, the bottom of the fore side of the equipment is prevented from colliding with the surfaces of the L-shaped brackets.

The slidable members each have a tilt angle of approximately 0°. The slidable members, stoppers, and knobs are formed so as to be respectively integrated in the form of continuous sheets, and the installation jig is therefore easily manufactured.

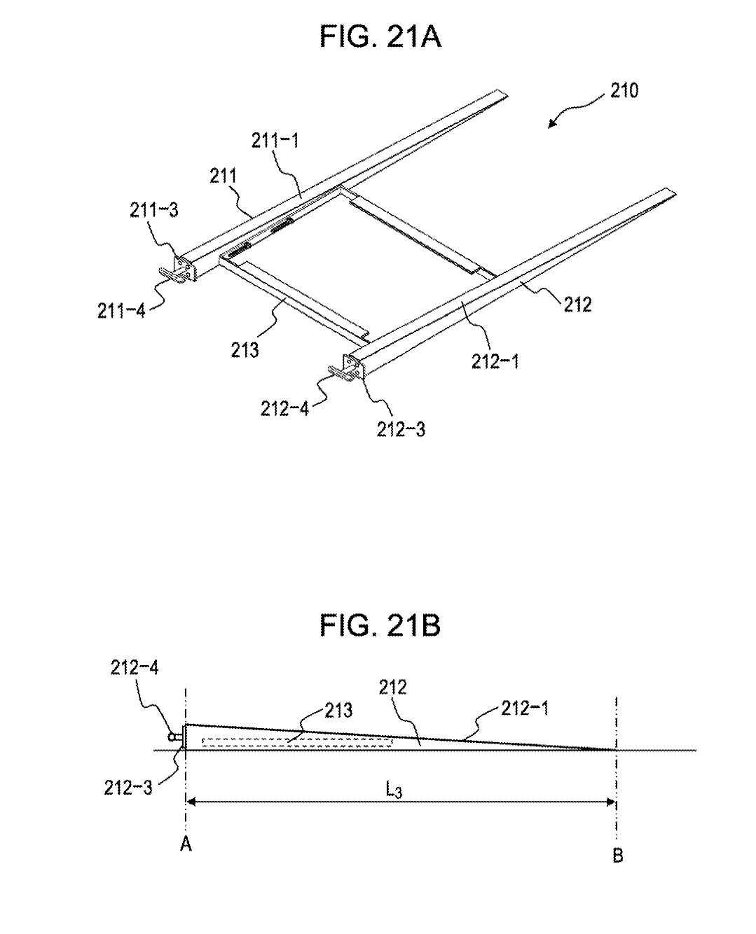

FIGS. 21A and 21B each illustrate an installation jig of a sixth embodiment.

FIG. 21A illustrates the appearance of an installation jig 210 viewed from the right-side front thereof. FIG. 21B illustrates the installation jig 210 viewed from the right side. With reference to FIG. 21A, a slidable member 211 has a first inclined surface 211-1 extending in the entire length of the slidable member 211, a slidable member 212 has a first inclined surface 212-1 extending in the entire length of the slidable member 212, and a second inclined surfaces are not provided. The size of each of the inclined surfaces is determined without considering the position of the center of gravity of equipment to be installed, and the equipment can be supported by the entire inclined surfaces regardless of the position of the center of gravity of the equipment. Simple configuration is therefore provided.

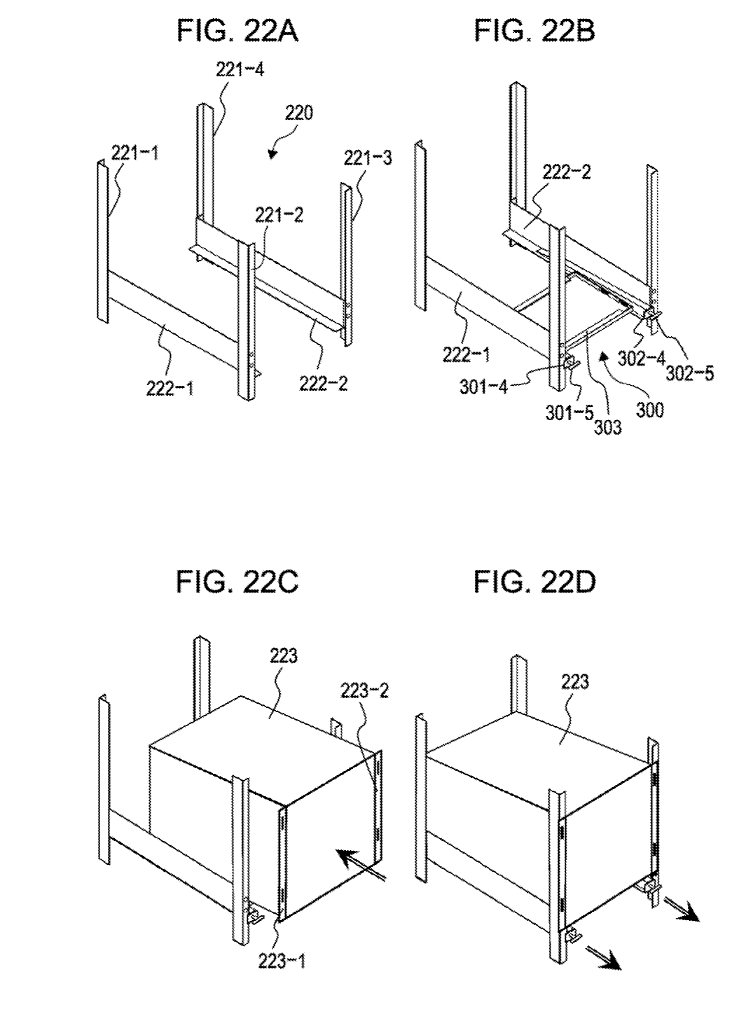

FIGS. 22A to 22D each illustrate an example in which an installation jig is used. FIG. 22A illustrates part of the inside of a rack 220 in which equipment is installed. Although illustration of the entire appearance of the rack 220 is omitted, for example, the rack 220 has a configuration in which four steel columns are vertically provided and in which upper and lower steel plates are respectively welded to the upper and lower portions of the four columns. Four steel inner columns 221-1 to 221-4 each having an L-shaped cross-sectional surface are provided to the inside of the rack 220, and the upper and lower plates are individually welded to the two ends of each of the columns 221-1 to 221-4. An L-shaped bracket 222-1 is fixed to the inner columns 221-1 and 221-2 with screws such that a horizontal surface of the L-shaped bracket 222-1 (surface of an L-shaped bracket) faces the inside of the rack 220, the screws being inserted in a direction from the near side to the depth side. An L-shaped bracket 222-2 is similarly fixed to the inner columns 221-3 and 221-4 with screws such that the horizontal surface of the L-shaped bracket 222-2 faces the inside of the rack 220 at the height the same as that of the L-shaped bracket 222-1. The L-shaped brackets 222-1 and 222-2 form a pair. The L-shaped bracket 222-1 and the L-shaped bracket 222-2 may be welded to the inner columns 221-1 and 221-2 and to the inner columns 221-3 and 221-4, respectively.

FIG. 22B illustrates a state in which the installation jig 300 is placed on surfaces of the L-shaped brackets 222-1 and 222-2. In the placement, the two bottoms 301-10 and 302-10 of the installation jig 300 are respectively placed on the surfaces of the L-shaped brackets 222-1 and 222-2 from the near side of the rack 220 (the side on which inner columns 221-2 and 221-3 are provided). The stoppers 301-4 and 302-4 of the installation jig 300 are brought into abutting on the inner columns 221-2 and 221-3, respectively. By virtue of such a configuration, the installation jig 300 is set at a specific position on the surfaces of the L-shaped brackets 222-1 and 222-2 and is prevented from moving to the depth side inside the rack 220 (the side on which the inner columns 221-1 and 221-4 are provided).

FIG. 22C illustrates a state in which equipment 223 is pushed into the depth side inside the rack 220. The equipment 223 is supported by a lifter (not illustrated) or two to three persons, and the end of the bottom of the equipment 223 is then placed on the L-shaped brackets 222-1 and 222-2. The equipment 223 is then pushed into a predetermined position inside the rack 200. At such a predetermined position, the fore-side end of the bottom of the equipment 223 abuts on dampers 222-1-1 and 222-2-1 (not illustrated) and then contacts the surfaces of the L-shaped brackets 222-1 and 222-2, the dampers 222-1-1 and 222-2-1 being respectively provided on surfaces of the L-shaped brackets 222-1 and 222-2. In this case, the dampers 222-1-1 and 222-2-1 may not be provided, and a configuration in which the equipment 223 moderately abuts on protrusions (not illustrated) that project from the inner columns 221-1 and 221-4 may be provided.

FIG. 22D illustrates a state in which the installation jig 300 is withdrawn from the equipment 223 to the near side, the equipment 223 having been pushed into the predetermined position inside the rack 220. Fixing portions 223-1 and 223-2 of the equipment 223 which has been pushed into the predetermined position are temporarily fixed to the screw holes of the inner columns 221-2 and 221-3 by using movement-inhibiting members such as screws, respectively.

By virtue of such a configuration, in the case where the installation jig 300 is withdrawn to the near side, the equipment 223 is prevented from moving to the near side of the rack 220. In this case, the equipment 223 may not be fixed to the rack 220 when the installation jig 300 is withdrawn. The sliding surfaces of the installation jig 300 are inclined, and a pair of the slidable members are individually withdrawn, particularly thereby preventing the movement of the equipment 223 to the near side.

The knobs 301-5 and 302-5 are gripped, and the slidable members 301 and 302 of the installation jig 300 are then alternately withdrawn in a predetermined stroke, respectively. After the withdrawing has been finished, the fixing portions 223-1 and 223-2 of the equipment 223 which have been temporarily fixed to the screw holes of the inner columns 221-2 and 221-3 with screws are completely fixed, thereby completing the installation of the equipment 223. Meanwhile, in the case where the equipment 223 does not have the fixing portions 223-1 and 223-2, the movement-inhibiting members which serve to fix the equipment 223 to the rack 220 may not be used if the equipment 223 does not move to the near side during the withdrawing of the installation jig 300.

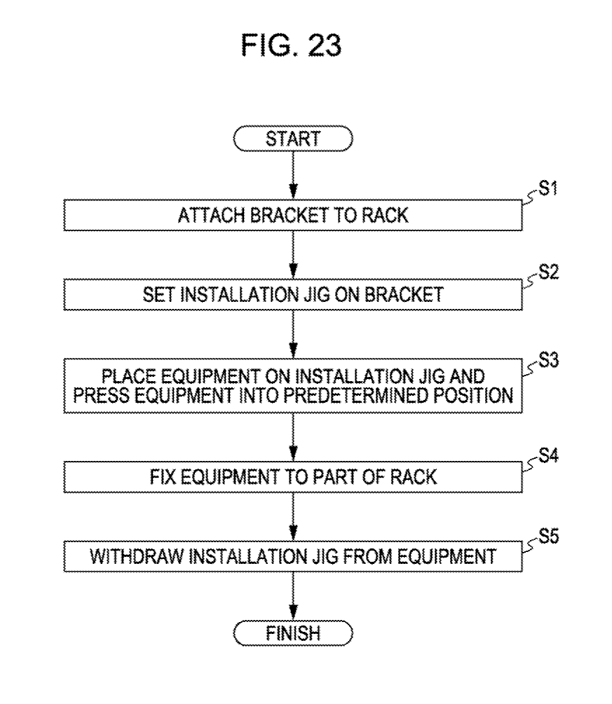

FIG. 23 is a flowchart illustrating an installation method. The flow of the installation method in which the installation jig is used is described on the basis of the example illustrated in FIGS. 22A to 22D.

First, a pair of brackets are screwed to a rack (S1). The brackets may be preliminarily welded to the rack. For example, L-shaped rigid steel brackets having L-shaped cross-sectional surfaces are used, and the L-shaped brackets are fixed to columns inside the rack such that horizontal surfaces (surfaces of the L-shaped brackets) of the L-shaped brackets are positioned at the same height. The surfaces of the L-shaped brackets have smoothness. The vertically extending portions of the L-shaped brackets function as a guide which prevents equipment and an installation jig from deviating to the left and right side. In a pair of the L-shaped brackets, the surfaces of the L-shaped brackets face the inside of the rack, thereby supporting the equipment to be installed.

The installation jig is subsequently set on the brackets (S2). The installation jig 300 is, for example, employed as such an installation jig. The bottoms of the slidable members of the installation jig are placed on the surfaces of the L-shaped brackets, and stoppers 301-4 and 302-4 of the installation jig are brought into abutting on columns inside the rack. In such a state, users are needed to confirm that the installation jig 300 does not move on the surfaces of the L-shaped brackets to the depth side inside the rack.

The equipment 223 to be installed in the rack is supported by a lifter or two to three persons, and the end of the bottom of the equipment 223 is then placed on the L-shaped brackets. The equipment 223 is then pushed into a predetermined position on the depth side inside the rack (S3). Such a predetermined position refers to a position at which the fore-side end of the bottom of the equipment 223 abuts on the two dampers 222-1-1 and 222-2-1 provided on the surfaces of the L-shaped brackets. At such a predetermined position, positional relationship between the L-shaped brackets and the slidable members and tilt angles of the inclined surfaces of the slidable members are determined such that the fore-side end of the bottom of the equipment 223 abuts on the surfaces of the L-shaped brackets. The stoppers 301-4 and 302-4 of the installation jig are brought into abutting on the columns inside the racks when the installation jig is placed on the L-shaped brackets, thereby preliminarily determining the positional relationship between the L-shaped brackets and the slidable members.

After the equipment 223 has reached a predetermined position, the equipment 223 is fixed to part of the rack with movement-inhibiting members such as screws (S4). The equipment 223 which has been reached a predetermined position is placed on the inclined surfaces of the slidable members and tilts with respect to the horizontal plane. In the case where the installation jig 300 on which the equipment 223 is placed is withdrawn, the movement of the equipment 223 to the near side needs to be prevented, and degree of freedom needs to be secured in a vertical direction in order to shift the tilted equipment 223 to a horizontal state. The state in which the equipment 223 is fixed to part of the rack refers to preventing the movement of the equipment 223 to the near side and refers to fixing the equipment 223 to part of the rack with movement-inhibiting members which enable the equipment 223 to be moved in a vertical direction. Elongate holes each having a predetermined length in a vertical direction are, for example, formed as the screw insertion holes of the fixing portions 223-1 and 223-2 of the equipment 223.

The installation jig 300 is subsequently withdrawn from the equipment 223 (S5). Knobs provided to the slidable members of the installation jig 300 are gripped, and the slidable members are then alternately withdrawn in stages in a predetermined stroke. The slidable members are withdrawn in stages, for example, in a stroke (S) of 80 mm. After the withdrawing has been finished, the screws which have been used to temporarily fix the equipment 223 to part of the rack are removed and are then replaced with other screws that are used for actually fixing the equipment 223, thereby completing the installation.

In the case where a configuration in which the screws used for the temporary fixing can be directly used for the actual fixing is employed, the screws may be directly fastened to actually fix the equipment 223. In the case where any of the installation jigs 180, 190, 200, and 210 is employed as an installation jig, a pair of the slidable members may be simultaneously withdrawn.

By virtue of the techniques disclosed in embodiments of the application, use of the installation jig for installing equipment in a rack enables the equipment to be less likely to be subjected to shock and enables the equipment to be slid to a predetermined position inside the rack with further small force.

Furthermore, a position on which the installation jig is set can be determined, the unwanted movement of the installation jig to the fore side can be prevented, and force for withdrawing the installation jig to the near side can be decreased.

Furthermore, the first inclined surface is formed such that the fore side of the bottom of the equipment which has been pushed into a predetermined position inside the rack is positioned at the height the same as those of the surfaces of the brackets. By virtue of such a configuration, because the fore side of the bottom of the equipment is prevented from contacting the surfaces of the brackets before the equipment reaches a predetermined position inside the rack, the rapid increase of force for pushing the equipment is prevented, and the surfaces of the brackets are not damaged by the fore side of the bottom of the equipment.

Moreover, in addition to a first inclined surface, a second inclined surface is formed so as to have a larger tilt angle with respect to the horizontal plane relative to the tilt angle of the first inclined surface, thereby being able to decrease the total lengths of the slidable members. The installation jig can be therefore easily withdrawn with the result that the number of operational processes can be decreased. In addition, in the case where the installation jig is withdrawn from the equipment, the fore side of the bottom of the equipment can be prevented from swiftly contacting the surfaces of the brackets, thereby being able to suppress shock which acts on the equipment.

In a technique disclosed in embodiments of the application, in the case where equipment is installed in a rack, the rack is less likely to be subjected to shock. In addition, the equipment can be slid to a predetermined position inside the rack with small force. Furthermore, the installation jig is prevented from being moved to the fore side. Moreover, in the case where the installation jig is withdrawn from the equipment to the near side, an advantageous effect in which force for the withdrawing can be reduced is provided.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiments of the present invention have been described in detail, it should be understood that the various changes, substitutions, and alterations could be made hereto without departing from the spirit and scope of the invention.

What is claimed is:

1. An installation jig used for installing information equipment in a rack, the installation jig comprising:
a pair of slidable members extending in a direction heading from a near side to a fore side of a rack, wherein an information equipment is pushed from the near side to the fore side of the rack in installation;
stoppers preventing the slidable members to be pushed over a predetermined position in the fore side; and
knobs pulling out the slidable members from the near side, wherein
the slidable members each have an inclined surface with a planar portion and each have a bottom with a planar portion, the bottom being formed at the side opposite to the inclined surface, wherein
a height between the bottom and the inclined surface is decreased from the near side to the fore side,
the inclined surface and the bottom is formed by using a material with a low friction coefficient,
the bottom is placed at a predetermined position on horizontal surfaces of a pair of brackets provided to the rack, the horizontal surfaces being positioned at the same height, and
the information equipment is slid on the inclined surface from the near side to the fore side with the result that the fore-side end of the information equipment abuts on the horizontal surfaces.

2. The installation jig according to claim 1, wherein
the slidable members each include a first inclined surface with a planar portion and each include a second inclined surface extending from the first inclined surface to the fore side of the first inclined surface and having a sharper tilt angle with respect to the horizontal plane relative to the tilt angle of the first inclined surface, wherein
a height between the bottom and each of the first and second inclined surfaces is decreased from the near side to the fore side,
the first and second inclined surfaces are formed by using a material with a low friction coefficient,
the bottom is placed at a predetermined position on horizontal surfaces of a pair of brackets provided to the rack, the horizontal surfaces being positioned at the same height,
the information equipment is slid on the first inclined surface from the near side to the fore side with the result that the fore-side end of the information equipment abuts on a predetermined position on the horizontal surfaces, and
an inter-inclined surface region which is a minimum rectangular area including a pair of the first inclined surfaces then intersects a vertical line extending from the position of the center of gravity of the information equipment.

3. The installation jig according to claim 1, further comprising rigid connection members which serve to connect the slidable members with each other.

4. The installation jig according to claim 3, wherein the slidable members are capable of moving to the near side within a predetermined range with respect to the connection members.

5. A method for installing information equipment in a rack, the method comprising:
preparing an installation jig which includes a pair of slidable members extending in a direction heading from a near side to a fore side of a rack; wherein
the information equipment is pushed from the near side to the fore side of the rack in installation,
stoppers preventing the slidable members to be pushed over a predetermined position in the fore side,
knobs pulling out the slidable members from the near side, wherein
the slidable members each including at least one inclined surface with a planar portion and each including a bottom which are positioned at the side opposite to the inclined surface and which have a planar portion,
the bottom forming a height with the inclined surface such that the height is decreased from the near side to the fore side, and the inclined surface and the bottom being formed by using a material with a low friction coefficient;
placing the bottom at a predetermined position on horizontal surfaces of a pair of brackets provided to the rack with the result that the stoppers abut on part of the rack, the horizontal surfaces being positioned at the same height;
placing part of the bottom of the information equipment on a near-side end of the inclined surface;
applying external force to the information equipment to the fore side to slide the information equipment on the inclined surface with the result that the information equipment is pushed into the rack;
bringing the fore-side end of the information equipment into abutting on the horizontal surfaces;
applying external force to the knobs to the near side to withdraw the installation jig from the information equipment; and
fixing the information equipment to the rack.

6. The installation jig according to claim 1, wherein
the slidable members, stoppers, and knobs are formed so as to be respectively integrated in the form of continuous sheets,
at least the top and rear surfaces of each of the slidable members are formed by using a material with a low friction coefficient, and
in the case where the rear surfaces of the slidable members are placed at a specific position on horizontal surfaces of a pair of brackets provided to the rack, the fore-side ends of the slidable members on the horizontal surfaces are located at any one of the position the same as the fore-side end of the information equipment at a predetermined position; and
a position on the near side relative to such a position, the horizontal surfaces being positioned at the same height.

7. The installation jig according to claim 6, wherein a height between the top and rear surfaces of each of the slidable members is decreased from the near side to the fore side.

8. The installation jig according to claim 6, wherein the slidable members each have uniform thickness.

9. A method for installing information equipment in a rack according to claim 5, wherein
the slidable members, stoppers, and knobs being formed so as to be respectively integrated in the form of continuous sheets, the slidable members each having a distance from the stopper to the fore side, the distance being any one of length the same as the length to the fore-side end of the information equipment at a predetermined position and length shorter than such a length, and at least the top and rear surfaces of each of the slidable members being formed by using a material with a low friction coefficient;
placing the installation jig at a predetermined position on horizontal surfaces of a pair of brackets provided to the rack with the result that the stoppers abut on part of the rack, the horizontal surfaces being positioned at the same height;
placing part of the bottom of the information equipment on near-side ends of the top surfaces;
applying external force to the information equipment to the fore side to slide the information equipment on the top surfaces with the result that the information equipment is pushed into the rack;
stopping the information equipment at a predetermined position;
applying external force to the knobs to the near side to withdraw the installation jig from the information equipment; and
fixing the information equipment to the rack.
